(19) United States
(12) Patent Application Publication
(10) Pub. No.: US 2022/0315868 A1
(43) Pub. Date: Oct. 6, 2022

(54) CLEANING SOLUTION AND CLEANING METHOD

(71) Applicant: FUJIFILM Corporation, Tokyo (JP)

(72) Inventor: Tetsuya KAMIMURA, Haibara-gun (JP)

(73) Assignee: FUJIFILM Corporation, Tokyo (JP)

(21) Appl. No.: 17/840,138

(22) Filed: Jun. 14, 2022

Related U.S. Application Data
(63) Continuation of application No. PCT/JP2020/043458, filed on Nov. 20, 2020.

(30) Foreign Application Priority Data
Dec. 26, 2019 (JP) 2019-236312

(51) Int. Cl. C11D 11/00; C11D 7/32; C11D 7/36; H01L 21/02

(52) U.S. Cl. CPC C11D 11/0047; C11D 7/3245; C11D 7/36; C11D 7/3218; C11D 7/3281; H01L 21/02074

(57) ABSTRACT

An object of the invention is to provide a cleaning liquid for semiconductor substrates having undergone CMP, the cleaning liquid being excellent in cleaning performance and corrosion prevention performance with respect to copper-containing and cobalt-containing metal films. Another object of the invention is to provide a method of cleaning semiconductor substrates having undergone CMP. A cleaning liquid of the invention is for semiconductor substrates having undergone CMP and includes: a component A that is an amino acid having one carboxyl group; a component B that is at least one selected from the group consisting of an aminopolycarboxylic acid and a polyphosphonic acid; and a component C that is an aliphatic amine (provided that the component A, the aminopolycarboxilic acid and a quaternary ammonium compound are excluded). The mass ratio of the component B content to the component A content is 0.2 to 10, and the mass ratio of the component C content to the sum of the component A content and the component B content is 5 to 100.

### CROSS-REFERENCE TO RELATED APPLICATIONS

This application is a Continuation of PCT International Application No. PCT/JP2020/043458 filed on Nov. 20, 2020, which claims priority under 35 U.S.C. § 119(a) to Japanese Patent Application No. 2019-236312 filed on Dec. 26, 2019. The above application is hereby expressly incorporated by reference, in its entirety, into the present application.

### BACKGROUND OF THE INVENTION

The present invention relates to a cleaning liquid for semiconductor substrates and a method of cleaning semiconductor substrates.

Semiconductor devices such as charge-coupled devices (CCDs) and memories are manufactured by forming fine electronic circuit patterns on substrates using the photolithography technology. Specifically, a semiconductor device is manufactured by forming a resist film on a laminate including a metal film which is a wiring material, an etching stop layer and an interlayer dielectric layer on a substrate and carrying out a photolithography step and a dry etching step (e.g., plasma etching).

In some cases, a dry etching residue (for instance, metal components such as titanium-based metal derived from a metallic hard mask, or organic components derived from a photoresist film) remains on a substrate having undergone the dry etching step.

In manufacture of semiconductor devices, a chemical mechanical polishing (CMP) process is sometimes carried out to planarize a surface of a substrate having a metal wiring film, a barrier metal, an insulating film and the like by use of an abrasive slurry containing fine abrasive particles (e.g., silica, alumina). In the CMP process, metal components derived from the fine abrasive particles used in the CMP process and from the metal wiring film, the barrier metal and/or the like having been polished tend to remain on the surface of the semiconductor substrate after polishing.

Since those residues may cause a short-circuit between wires and affect electrical properties of a semiconductor, a cleaning step for removing the residues from the surface of the semiconductor substrate is usually carried out.

For instance, JP 2016-519423 A describes an aqueous cleaning composition for post copper chemical mechanical planarization, the composition comprising an organic base, a copper etchant, an organic ligand, a corrosion inhibitor which is a hydrazide compound, and water, with the organic base, the copper etchant, the organic ligand, and the corrosion inhibitor being contained at respective specific concentrations.

### SUMMARY OF THE INVENTION

The present inventor have made a study on a cleaning liquid for semiconductor substrates having undergone CMP by reference to, for example, JP 2016-519423 A and as a result found that when a copper-containing residue and a cobalt-containing residue remain on a surface of a semiconductor substrate, the rates of reaction with those residues greatly vary among components contained in the cleaning liquid and that there is a room for further improvement in cleaning performance and corrosion prevention performance of a cleaning liquid with respect to semiconductor substrates having undergone CMP.

An object of the present invention is to provide a cleaning liquid for semiconductor substrates having undergone CMP, the cleaning liquid being excellent in cleaning performance and corrosion prevention performance with respect to a copper-containing metal film and a cobalt-containing metal film. Another object of the present invention is to provide a method of cleaning semiconductor substrates having undergone CMP.

The present inventors found that the above objects can be attained with the following configuration.

[1] A cleaning liquid for semiconductor substrates having undergone a chemical mechanical polishing process, the cleaning liquid comprising: a component A that is an amino acid having one carboxyl group; a component B that is at least one selected from the group consisting of an aminopolycarboxylic acid and a polyphosphonic acid; and a component C that is an aliphatic amine (provided that the component A, the aminopolycarboxilic acid and a quaternary ammonium compound are excluded), wherein a mass ratio of a content of the component B to a content of the component A is 0.2 to 10, and a mass ratio of a content of the component C to a sum of the content of the component A and the content of the component B is 5 to 100.
[2] The cleaning liquid according to [1], wherein the component A includes at least one selected from the group consisting of glycine, histidine, cysteine, arginine, methionine, sarcosine, and alanine.
[3] The cleaning liquid according to [1] or [2], wherein the component B includes at least one selected from the group consisting of diethylenetriamine pentaacetic acid, ethylenediamine tetraacetic acid, trans-1,2-diaminocyclohexane tetraacetic acid, nitrilotris(methylenephosphonic acid), and ethylenediamine tetra(methylenephosphonic acid).
[4] The cleaning liquid according to any one of [1] to [3], wherein the component C includes an amino alcohol.
[5] The cleaning liquid according to any one of [1] to [4], further comprising a component D that is at least one selected from the group consisting of a nitrogen-containing heteroaromatic compound, a reducing agent, an anionic surfactant, and a chelating agent (provided that compounds included in the component A, the component B and the component C are excluded).
[6] The cleaning liquid according to [5], wherein a mass ratio of a content of the component D to the sum of the content of the component A and the content of the component B is 0.1 to 20.
[7] The cleaning liquid according to any one of [1] to [6], further comprising a quaternary ammonium compound that is a compound having a quaternary ammonium cation, or a salt thereof.
[8] The cleaning liquid according to [7], wherein the quaternary ammonium cation in the quaternary ammonium compound has an asymmetric structure.
[9] The cleaning liquid according to [7] or [8], wherein the quaternary ammonium compound comprises two or more quaternary ammonium compounds.
[10] The cleaning liquid according to any one of [1] to [9], further comprising two or more reducing agents.
[11] The cleaning liquid according to any one of [1] to [10], wherein the cleaning liquid has a pH of 8.0 to 12.0 at 25° C.
[12] The cleaning liquid according to any one of [1] to [11], wherein the semiconductor substrate has a metal film containing at least one selected from the group consisting of copper and cobalt.
[13] The cleaning liquid according to any one of [1] to [12], wherein the semiconductor substrate has a metal film containing tungsten.
[14] A method of cleaning semiconductor substrates, the method comprising a step of cleaning a semiconductor substrate having undergone a chemical mechanical polishing process by applying the cleaning liquid according to any one of [1] to [13] to the semiconductor substrate.

The present invention makes it possible to provide a cleaning liquid for semiconductor substrates having undergone CMP, the cleaning liquid being excellent in cleaning performance and corrosion prevention performance with respect to a copper-containing metal film and a cobalt-containing metal film. The present invention also makes it possible to provide a method of cleaning semiconductor substrates having undergone CMP.

### DETAILED DESCRIPTION OF THE INVENTION

One exemplary embodiment of the invention is described below.

In this specification, a numerical range expressed in the form of “A to B” should read as a range including both the values A and B as the range's lower and upper limits, respectively.

In this specification, when a certain component comprising two or more types is present, the “content” of the certain component means the total content of the two or more types.

In this specification, “ppm” means “parts per million (10⁻⁶),” and “ppb” means “parts per billion (10⁻⁹).”

In compounds described in this specification, isomers (compounds with the same number of atoms but different structures), optical isomers, and isotopes may be included unless particularly limited. As isomers and isotopes, only one type or plural types may be included.

In this specification, “psi” refers to “pound-force per square inch,” and 1 psi=6894.76 Pa.

The cleaning liquid of the present invention (hereinafter also simply called “cleaning liquid”) is a cleaning liquid for semiconductor substrates having undergone a chemical mechanical polishing (CMP) process, the cleaning liquid comprising: a component A that is an amino acid having one carboxyl group; a component B that is at least one selected from the group consisting of an aminopolycarboxylic acid and a polyphosphonic acid; and a component C that is an aliphatic amine (provided that the component A, the aminopolycarboxilic acid and a quaternary ammonium compound are excluded). The mass ratio of the component B content to the component A content is 0.05 to 20. The mass ratio of the component C content to the sum of the component A content and the component B content is 5 to 100.

The present inventor has found that when a cleaning liquid contains the component A, the component B and the component C and the ratio among the contents of the components A, B and C is specified, the cleaning performance and the corrosion prevention performance with respect to a copper-containing metal film and a cobalt-containing metal film (hereinafter also simply called “effects of the invention”) in a step of cleaning a semiconductor substrate having undergone CMP are improved.

Note that in connection with an object to be cleaned with the cleaning liquid and the effects of the invention, the expression “a semiconductor substrate has a copper-containing metal film and a cobalt-containing metal film” refers to the case where the copper-containing metal film is the same film as the cobalt-containing metal film (i.e., a single metal film contains both copper and cobalt) and also the case where the copper-containing metal film and the cobalt-containing metal film are different metal films.

Although not clear, the precise mechanism as to how the cleaning liquid brings the effects of the invention is assumed as follows. The present inventor found that many of components contained in a cleaning liquid for semiconductor substrates have the rate of reaction with cobalt lower than the rate of reaction with copper by about 10² to about 10⁸. Accordingly, when a copper-containing residue (hereinafter also referred to as “Cu residue”) and a cobalt-containing residue (hereinafter also referred to as “Co residue”) remain on a surface of a semiconductor substrate, a cleaning component contained in a cleaning liquid shows low reactivity with respect to the Co residue, and in some cases it is difficult to obtain high cleaning performance. The present inventor assumes that, in contrast, since the component A whose rate of reaction with cobalt and rate of reaction with copper are relatively close is used in a specific amount in the cleaning liquid of the invention, the cleaning liquid can have improved cleaning performance with respect to a Co residue in addition to excellent corrosion prevention performance and cleaning performance with respect to a Cu residue when used to a semiconductor substrate having a copper-containing metal film and a cobalt-containing metal film.

### [Cleaning Liquid]

Each component contained in the cleaning liquid is described below.

### [Component A]

The cleaning liquid contains the component A that is an amino acid having one carboxyl group.

The component A is not particularly limited as long as it is a compound having one carboxyl group and one or more amino groups in the molecule.

Examples of the component A include glycine, serine, α-alanine (2-aminopropionic acid), β-alanine (3-aminopropionic acid), lysine, leucine, isoleucine, cysteine, methionine, ethionine, threonine, tryptophan, tyrosine, valine, histidine, histidine derivatives, asparagine, glutamine, arginine, proline, phenylalanine, sarcosine, the compounds described in paragraphs [0021] to [0023] of JP 2016-086094 A, and salts thereof. For the histidine derivatives, the compounds described in JP 2015-165561 A, JP 2015-165562 A and the like can be applied, and the contents thereof are incorporated in the present specification. Examples of the salts include alkali metal salts such as a sodium salt and a potassium salt, ammonium salts, carbonates, and acetates.

The number of amino groups in the component A is preferably 1 to 4, more preferably 1 or 2, and even more preferably 1.

The component A is preferably of low molecular weight. Specifically, the molecular weight of the component A is preferably not more than 600, more preferably not more than 450 and even more preferably not more than 300. The lower limit thereof is not particularly limited and is preferably not less than 70.

The number of carbon atoms in the component A is preferably not more than 15, more preferably not more than 12 and even more preferably not more than 8. The lower limit thereof is not particularly limited and is preferably not less than 1.

For the component A, preferred is glycine, histidine, cysteine, arginine, methionine, sarcosine, or alanine because this leads to more excellent cleaning performance (particularly with respect to a Co-containing metal film), more preferred is glycine, histidine, cysteine, or alanine, and even more preferred is glycine, histidine, or alanine because this leads to even more excellent cleaning performance.

The component A has a rate of reaction (rate of solvent exchange) with Co²⁺ of preferably 10⁴ to 10⁹ and more preferably 10⁶ to 10⁹ because this leads to more excellent cleaning performance with respect to a Co-containing metal film. Among specific components A listed above, a compound having a rate of reaction of 10⁴ to 10⁹ is glycine, histidine, cysteine, methionine, or alanine.

The rate of reaction (rate of solvent exchange) of a compound with Co²⁺ can be measured by cooling the compound with a criostat and tracking increase and decrease of peak absorption through continuous measurement using a spectrometer. For instance, the rate can be measured by tracking spectroscopic peaks appearing in the wavelength range of 400 to 700 nm at a liquid nitrogen temperature (77K). The rate of reaction here is a value at 23° C. and therefore converted from the measured value to a value at room temperature.

The components A may be used singly or in combination of two or more.

The component A content of the cleaning liquid is preferably not less than 0.003 mass %, more preferably not less than 0.005 mass % and even more preferably not less than 0.01 mass % based on the total mass of the cleaning liquid because this leads to more excellent cleaning performance (particularly with respect to a Co-containing metal film). The upper limit thereof is not particularly limited and is preferably not more than 2.0 mass %, more preferably not more than 1.0 mass %, even more preferably not more than 0.8 mass % and particularly preferably not more than 0.5 mass % based on the total mass of the cleaning liquid because this leads to more excellent corrosion prevention performance (particularly with respect to a Cu- or Co-containing metal film).

Further, the component A content is preferably not less than 0.01 mass %, more preferably not less than 0.02 mass % and even more preferably not less than 0.05 mass % based on the total mass of components, excluding a solvent, in the cleaning liquid. The upper limit thereof is not particularly limited and is preferably not more than 15.0 mass %, more preferably not more than 10.0 mass % and even more preferably not more than 8.0 mass % based on the total mass of components, excluding a solvent, in the cleaning liquid.

In this specification, the expression “the total mass of components, excluding a solvent, in the cleaning liquid” refers to the sum of the contents of all components contained in the cleaning liquid, excluding a solvent. The simple term “solvent” includes both water and an organic solvent.

### [Component B]

The cleaning liquid contains the component B that is at least one selected from the group consisting of an aminopolycarboxylic acid and a polyphosphonic acid.

The aminopolycarboxylic acid is a compound having one or more amino groups and two or more carboxyl groups in the molecule. The polyphosphonic acid is a compound having two or more phosphonic acid groups in the molecule.

### <Aminopolycarboxylic Acid>

The aminopolycarboxylic acid is a compound having one or more amino groups and two or more carboxyl groups as coordination groups in the molecule.

Examples of the aminopolycarboxylic acid include aspartic acid, glutamic acid, butylene diamine tetraacetic acid, diethylenetriamine pentaacetic acid (DTPA), ethylenediamine tetrapropionic acid, triethylenetetramine hexaacetic acid, 1,3-diamino-2-hydroxypropane-N,N,N′,N′-tetraacetic acid, propylenediamine tetraacetic acid, ethylenediamine tetraacetic acid (EDTA), trans-1,2-diaminocyclohexane tetraacetic acid (CyDTA), ethylenediamine diacetic acid, ethylenediamine dipropionic acid, 1,6-hexamethylene-diamine-N,N,N′,N′-tetraacetic acid, triethylenetetramine-N,N,N′,N″,N′″,N″′-hexaacetic acid (TTHA), N,N-bis(2-hydroxybenzyl)ethylenediamine-N,N-diacetic acid, diaminopropane tetraacetic acid, 1,4,7,10-tetraazacyclododecane-tetraacetic acid, diaminopropanol tetraacetic acid, (hydroxyethyl)ethylenediamine triacetic acid, and iminodiacetic acid (IDA).

The number of amino groups in the aminopolycarboxylic acid is preferably 1 to 5, more preferably 2 to 4, and even more preferably 3 or 4. The number of carboxyl groups in the aminopolycarboxylic acid is preferably 2 to 5, more preferably 3 to 5, and even more preferably 4 or 5.

The number of carbon atoms in the aminopolycarboxylic acid is preferably not more than 15 and more preferably not more than 12. The lower limit thereof is not particularly limited and is preferably not less than 4 and more preferably not less than 6.

For the aminopolycarboxylic acid, DTPA, EDTA, or CyDTA is preferred, and DTPA or EDTA is more preferred because this leads to more excellent cleaning performance (particularly with respect to a Cu-containing metal film).

### <Polyphosphonic Acid>

The polyphosphonic acid is a compound having two or more phosphonic acid groups in the molecule.

Examples of the polyphosphonic acid include compounds represented by Formulae (P1), (P2) and (P3) below.

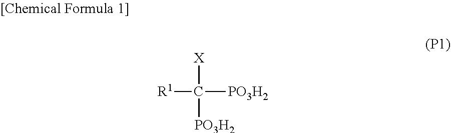

In the formula, X represents a hydrogen atom or a hydroxy group, and R¹ represents a hydrogen atom or an alkyl group having 1 to 10 carbon atoms.

The alkyl group having 1 to 10 carbon atoms represented by R¹ in Formula (P1) may be any of linear, branched and cyclic groups.

For R¹ in Formula (P1), an alkyl group having 1 to 6 carbon atoms is preferred, and a methyl group, an ethyl group, an n-propyl group, or an isopropyl group is more preferred.

It should be noted that n- represents a normal-type in specific examples of an alkyl group described in the present specification.

For X in Formula (P1), a hydroxy group is preferred.

For the polyphosphonic acid represented by Formula (P1), preferred is ethylidenediphosphonic acid, 1-hydroxyethylidene-1,1′-diphosphonic acid (HEDPO), 1-hydroxypropylidene-1,1′-diphosphonic acid, or 1-hydroxybutylidene-1,1′-diphosphonic acid.

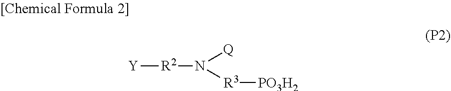

In the formula, Q represents a hydrogen atom or R³—PO₃H₂, R² and R³ each independently represent an alkylene group, and Y represents a hydrogen atom, —R³—PO₃H₂, or a group represented by Formula (P4) below.

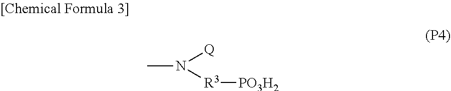

In the formula, Q and R³ are the same as those in Formula (P2).

Examples of the alkylene group represented by R² in Formula (P2) include a linear or branched alkylene group having 1 to 12 carbon atoms.

For the alkylene group represented by R², a linear or branched alkylene group having 1 to 6 carbon atoms is preferred, a linear or branched alkylene group having 1 to 4 carbon atoms is more preferred, and an ethylene group is even more preferred.

For the alkylene group represented by R³ in Formulae (P2) and (P4), examples thereof include a linear or branched alkylene group having 1 to 10 carbon atoms, with a linear or branched alkylene group having 1 to 4 carbon atoms being preferred, a methylene group or an ethylene group being more preferred, and a methylene group being even more preferred.

For Q in Formulae (P2) and (P4), —R³—PO₃H₂ is preferred.

For Y in Formula (P2), —R³—PO₃H₂ or a group represented by Formula (P4) is preferred, and a group represented by Formula (P4) is more preferred.

For the polyphosphonic acid represented by Formula (P2), preferred is ethylaminobis(methylenephosphonic acid), dodecylaminobis(methylenephosphonic acid), nitrilotris(methylenephosphonic acid) (NTPO), ethylenediamine bis(methylenephosphonic acid) (EDDPO), 1,3-propylenediamine bis(methylenephosphonic acid), ethylenediamine tetra(methylenephosphonic acid) (EDTPO), ethylenediamine tetra(ethylenephosphonic acid), 1,3-propylenediamine tetra(methylenephosphonic acid) (PDTMP), 1,2-diaminopropane tetra(methylenephosphonic acid), or 1,6-hexamethylenediamine tetra(methylenephosphonic acid).

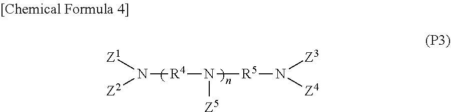

In the formula, R⁴ and R⁵ each independently represent an alkylene group having 1 to 4 carbon atoms, n represents an integer of 1 to 4, and at least four of Z¹ to Z⁴ and n moieties of Z⁵s represent a phosphonic acid group-containing alkyl group while the remainder represents an alkyl group.

The alkylene group having 1 to 4 carbon atoms represented by R⁴ and R⁵ in Formula (P3) may be a linear or branched group. Examples of the alkylene group having 1 to 4 carbon atoms represented by R⁴ and R⁵ include a methylene group, an ethylene group, a propylene group, a trimethylene group, an ethylmethylene group, a tetramethylene group, a 2-methylpropylene group, a 2-methyltrimethylene group, and an ethylethylene group, with an ethylene group being preferred.

For n in Formula (P3), 1 or 2 is preferred.

Examples of an alkyl group in the alkyl group and the phosphonic acid group-containing alkyl group represented by Z¹ to Z⁵ in Formula (P3) include a linear or branched alkyl group having 1 to 4 carbon atoms, with a methyl group being preferred.

The number of phosphonic acid groups in the phosphonic acid group-containing alkyl group represented by Z¹ to Z⁵ is preferably 1 or 2 and more preferably 1.

Examples of the phosphonic acid group-containing alkyl group represented by Z¹ to Z⁵ include a linear or branched alkyl group having 1 to 4 carbon atoms and one or two phosphonic acid groups, with a (mono)phosphonomethyl group or a (mono)phosphonoethyl group being preferred, and a (mono)phosphonomethyl group being more preferred.

For Z¹ to Z⁵ in Formula (P3), it is preferable that each of Z¹ to Z⁴ and n moieties of Z⁵s be the foregoing phosphonic acid group-containing alkyl group.

For the polyphosphonic acid represented by Formula (P3), preferred is diethylenetriamine penta(methylenephosphonic acid) (DEPPO), diethylenetriamine penta(ethylenephosphonic acid), triethylenetetramine hexa(methylenephosphonic acid), or triethylenetetramine hexa(ethylenephosphonic acid).

For the polyphosphonic acid used in the cleaning liquid, not only the polyphosphonic acids represented by Formulae (P1), (P2) and (P3) above but also the compounds described in paragraphs [0026] to [0036] of the description of WO 2018/020878 and the compounds ((co)polymers) described in paragraphs [0031] to [0046] of the description of WO 2018/030006 can be applied, and the contents thereof are incorporated in the present specification.

The number of phosphonic acid groups in the polyphosphonic acid is preferably 2 to 5, more preferably 2 to 4, and even more preferably 3 or 4.

The number of carbon atoms in the polyphosphonic acid is preferably not more than 15, more preferably not more than 12 and even more preferably not more than 8. The lower limit thereof is not particularly limited and is preferably not less than 3.

For the polyphosphonic acid, those compounds listed as preferable specific examples of the polyphosphonic acids represented by Formulae (P1), (P2) and (P3) above are preferred, and in terms of providing more excellent cleaning performance (particularly with respect to a Cu-containing metal film), NTPO or EDTPO is more preferred, and EDTPO is even more preferred.

The component B is preferably of low molecular weight. Specifically, the molecular weight of the component B is preferably not more than 600 and more preferably not more than 450. The lower limit thereof is not particularly limited and is preferably not less than 100.

For the component B, preferred is diethylenetriamine pentaacetic acid (DTPA), ethylenediamine tetraacetic acid (EDTA), trans-1,2-diaminocyclohexane tetraacetic acid (CyDTA), nitrilotris(methylenephosphonic acid) (NTPO), or ethylenediamine tetra(methylenephosphonic acid) (EDTPO), more preferred is DTPA, EDTA, CyDTA, or EDTPO, and even more preferred is DTPA, EDTA, or EDTPO because this leads to more excellent cleaning performance (particularly with respect to a Cu-containing metal film).

The component B has a first complex formation constant Kₘ₁ with respect to Co²⁺ of preferably 10 to 30 and more preferably 15 to 30 because this leads to more excellent cleaning performance with respect to a Co-containing metal film. Among the foregoing specific components B, exemplary compounds having a first complex formation constant Kₘ₁ of 10 to 30 include DTPA, EDTA, CyDTA, and TTHA.

The first complex formation constant Kₘ₁ of a compound can be obtained by a known method described below. Specifically, the coupling constant (complex formation constant) in a chelate formation reaction between a metal and a ligand can be obtained by Formula (1) below.

$$\begin{matrix}[ Mathematical Formula 1 ] & \\ M + L \vec{←} ML ( {K}_{ML} = \frac{[ ML ]}{[ M ] [ L \}} ) & ( 1 )\end{matrix}$$

In Formula (1), M is a metal, L is a ligand, and K_{ML} is a coupling constant. A variable related to the concentration of each component necessary for this calculation is not particularly limited as long as it has a primary correspondence relation with the concentration, and applicable variables include, for example, the concentration and the absorbance that are measured by known methods such as ultraviolet-visible spectroscopy, fluorescence intensity measurement, and NMR measurement.

The components B may be used singly or in combination of two or more.

The component B content of the cleaning liquid is not particularly limited and is preferably not less than 0.005 mass %, more preferably not less than 0.008 mass % and even more preferably not less than 0.01 mass % based on the total mass of the cleaning liquid because this leads to more excellent cleaning performance with respect to a Cu-containing metal film. The upper limit thereof is not particularly limited and is preferably not more than 2.0 mass %, more preferably not more than 1.5 mass % and even more preferably not more than 1.2 mass % based on the total mass of the cleaning liquid because this leads to more excellent corrosion prevention performance (particularly with respect to a Cu-containing metal film).

Further, the component B content is preferably not less than 0.02 mass %, more preferably not less than 0.05 mass % and even more preferably not less than 0.1 mass % based on the total mass of components, excluding a solvent, in the cleaning liquid. The upper limit thereof is not particularly limited and is preferably not more than 20.0 mass %, more preferably not more than 15.0 mass % and even more preferably not more than 10.0 mass % based on the total mass of components, excluding a solvent, in the cleaning liquid.

In the cleaning liquid of the invention, the mass ratio of the component B content to the component A content (component B content/component A content) is 0.2 to 10. The mass ratio of the component B content to the component A content within the above range allows both cleaning performance with respect to a Cu-containing metal film and that with respect to a Co-containing metal film to improve in good balance. The mass ratio of the component B content to the component A content is preferably 0.2 to 5 and more preferably 0.5 to 3.

### [Component C]

The cleaning liquid contains an aliphatic amine as the component C. Note that the aliphatic amine as the component C does not include the component A, the aminopolycarboxilic acid as the component B, and a quaternary ammonium compound.

The aliphatic amine is not particularly limited as long as it is for example a compound that is at least one selected from the group consisting of a primary amine having a primary amino group (—NH₂) in the molecule, a secondary amine having a secondary amino group (>NH) in the molecule, a tertiary amine having a tertiary amino group (>N—) in the molecule, and their salts, has no aromatic ring, and is not included in any of the component A, the aminopolycarboxilic acid and a quaternary ammonium compound.

Examples of a salt of at least one selected from the group consisting of the primary amine, the secondary amine and the tertiary amine (hereinafter also referred to as “primary to tertiary amines”) include a salt of an inorganic acid in which at least one non-metal selected from the group consisting of Cl, S, N and P is bonded to hydrogen, and preferred is a hydrochloride, a sulfate, or a nitrate.

Examples of the component C include an amino alcohol and an alicyclic amine, as well as an aliphatic monoamine compound and an aliphatic polyamine compound other than the amino alcohol and the alicyclic amine.

### <Amino Alcohol>

The amino alcohol is, of the primary to tertiary amines, a compound further having at least one hydroxylalkyl group in the molecule. The amino alcohol may have any of primary to tertiary amino groups and preferably has a primary amino group.

Examples of the amino alcohol include monoethanolamine (MEA), 2-amino-2-methyl-1-propanol (AMP), diethanolamine (DEA), triethanolamine (TEA), diethylene glycol amine (DEGA), tris(hydroxymethyl)aminomethane (Tris), 2-(methylamino)-2-methyl-1-propanol (N-MAMP), and 2-(2-aminoethylamino)ethanol.

Of these, AMP, N-MAMP, MEA, DEA, Tris, or DEGA is preferred, and AMP is more preferred.

### <Alicyclic Amine Compound>

The alicyclic amine compound is not particularly limited as long as it is a compound having a non-aromatic heterocyclic ring in which at least one of atoms constituting the ring is a nitrogen atom.

Examples of the alicyclic amine compound include a piperazine compound and a cyclic amidine compound.

The piperazine compound is a compound having a six-membered heterocyclic ring (piperazine ring) in which opposed —CH— groups in a cyclohexane ring are substituted with nitrogen atoms.

The piperazine compound may have a substituent on the piperazine ring. Examples of the substituent include a hydroxy group, an alkyl group having 1 to 4 carbon atoms that may have a hydroxy group, and an aryl group having 6 to 10 carbon atoms.

Examples of the piperazine compound include piperazine, 1-methylpiperazine, 1-ethylpiperazine, 1-propylpiperazine, 1-butylpiperazine, 2-methylpiperazine, 1,4-dimethylpiperazine, 2,5-dimethylpiperazine, 2,6-dimethylpiperazine, 1-phenylpiperazine, 2-hydroxypiperazine, 2-hydroxymethylpiperazine, 1-(2-hydroxyethyl)piperazine (HEP), N-(2-aminoethyl)piperazine (AEP), 1,4-bis(2-hydroxyethyl)piperazine (BHEP), 1,4-bis(2-aminoethyl)piperazine (BAEP), and 1,4-bis(3-aminopropyl)piperazine (BAPP), with preferred being piperazine, 1-methylpiperazine, 2-methylpiperazine, HEP, AEP, BHEP, BAEP, or BAPP, and more preferred being piperazine.

The cyclic amidine compound is a compound having a heterocyclic ring including an amidine structure (>N—C═N—) in the ring.

The number of atoms constituting the heterocyclic ring of the cyclic amidine compound is not particularly limited and is preferably 5 or 6 and more preferably 6.

Examples of the cyclic amidine compound include diazabicycloundecene (1,8-diazabicyclo[5.4.0]undec-7-ene: DBU), diazabicyclononene (1,5-diazabicyclo[4.3.0]non-5-ene: DBN), 3,4,6,7,8,9,10,11-octahydro-2H-pyrimido[1,2-a]azocine, 3,4,6,7,8,9-hexahydro-2H-pyrido[1,2-a]pyrimidine, 2,5,6,7-tetrahydro-3H-pyrrolo[1,2-a]imidazole, 3-ethyl-2,3,4,6,7,8,9,10-octahydropyrimido[1,2-a]azepine, and creatinine.

Examples of the alicyclic amine compound include, in addition to the foregoing examples, a compound having a five-membered heterocyclic ring with no aromatic properties such as 1,3-dimethyl-2-imidazolidinone or imidazolidinethione, and a compound having a seven-membered ring containing a nitrogen atom(s).

### <Aliphatic Monoamine Compound>

Examples of the aliphatic monoamine compound other than the amino alcohol and the alicyclic amine include a compound represented by Formula (a) below (hereinafter also referred to as “compound (a)”):

NHₓR₍₃₋ₓ₎ (a)

where R represents an alkyl group having 1 to 3 carbon atoms, and x represents an integer of 0 to 2.

Examples of the alkyl group having 1 to 3 carbon atoms include a methyl group, an ethyl group, an n-propyl group, and an isopropyl group, with an ethyl group or an n-propyl group being preferred.

Examples of the compound (a) include methylamine, ethylamine, propylamine, dimethylamine, diethylamine, trimethylamine, and triethylamine, with preferred being ethylamine, propylamine, diethylamine, or triethylamine.

Examples of the aliphatic monoamine compound other than the compound (a) include n-butylamine, 3-methoxypropylamine, tert-butylamine, n-hexylamine, cyclohexylamine, n-octylamine, 2-ethylhexylamine, and 4-(2-aminoethyl)morpholine (AEM).

### <Aliphatic Polyamine Compound>

Examples of the aliphatic polyamine compound other than the amino alcohol and the alicyclic amine include alkylene diamines such as ethylenediamine (EDA), 1,3-propanediamine (PDA), 1,2-propanediamine, 1,3-butanediamine, and 1,4-butanediamine, and polyalkyl polyamines such as diethylenetriamine (DETA), triethylenetetramine (TETA), bis(aminopropyl)ethylenediamine (BAPEDA), and tetraethylenepentamine.

For the component C, the compounds described in paragraphs [0034] to [0056] of the description of WO 2013/162020 can be applied, and the contents thereof are incorporated in the present specification.

The component C preferably further has one or more hydrophilic groups in addition to one of the primary to tertiary amino groups. Examples of the hydrophilic group include the primary to tertiary amino groups and a hydroxy group.

Examples of the amine compound as above include an amino alcohol having one or more primary to tertiary amino groups and one or more hydroxy groups, an aliphatic polyamine compound having two or more primary to tertiary amino groups, and of alicyclic amine compounds, a compound having two or more hydrophilic groups.

The upper limit of the total number of hydrophilic groups in the component C is not particularly limited and is preferably not more than 5 and more preferably not more than 4.

For the component C, preferred is the amino alcohol or the alicyclic amine compound, more preferred is monoethanolamine (MEA), 2-amino-2-methyl-1-propanol (AMP), 2-(methylamino)-2-methyl-1-propanol (N-MAMP), diethanolamine (DEA), diethylene glycol amine (DEGA), tris(hydroxymethyl)aminomethane (Tris), piperazine, N-(2-aminoethyl)piperazine (AEP), 1,4-bis(2-hydroxyethyl)piperazine (BHEP), 1,4-bis(2-aminoethyl)piperazine (BAEP), or 1,4-bis(3-aminopropyl)piperazine (BAPP), and even more preferred is AMP, MEA, or Tris.

The components C may be used singly or in combination of two or more.

The component C content of the cleaning liquid is not particularly limited and is preferably 0.03 to 30 mass %, more preferably 0.05 to 15 mass % and even more preferably 0.5 to 12 mass % based on the total mass of the cleaning liquid.

Further, the component C content is preferably 3.0 to 99.0 mass %, more preferably 5.0 to 98.0 mass % and even more preferably 20.0 to 95.0 mass % based on the total mass of components, excluding a solvent, in the cleaning liquid.

In the cleaning liquid of the invention, the mass ratio of the component C content to the sum of the component A content and the component B content (component C content/(component A content+component B content)) is 5 to 100. The mass ratio above being not less than 5 results in excellent corrosion prevention performance (particularly with respect to a Cu- and/or Co-containing metal film), while the mass ratio above being not more than 100 results in excellent cleaning performance (particularly with respect to a Cu-containing metal film). The mass ratio of the component C content to the sum of the component A content and the component B content is preferably 5 to 80 and more preferably 10 to 70.

### [Water]

The cleaning liquid preferably contains water as a solvent.

The type of water used in the cleaning liquid is not particularly limited as long as it has no bad influence on a semiconductor substrate, and distilled water, deionized water and pure water (ultrapure water) are usable. Pure water is preferred because it hardly contains impurities and its influence on a semiconductor substrate is smaller in a semiconductor substrate manufacturing process.

The water content of the cleaning liquid may be the balance other than the component A, the component B, the component C, and optional components to be described later. The water content is, for instance, preferably not less than 1 mass %, more preferably not less than 30 mass %, even more preferably not less than 60 mass %, and particularly preferably not less than 85 mass % based on the total mass of the cleaning liquid. The upper limit thereof is not particularly limited and is preferably not more than 99 mass % and more preferably not more than 95 mass % based on the total mass of the cleaning liquid.

### [Optional Component]

The cleaning liquid may contain other optional components in addition to the foregoing components. Optional components are described below.

### <Component D>

The cleaning liquid may contain a component D that is at least one selected from the group consisting of a nitrogen-containing heteroaromatic compound, a reducing agent, an anionic surfactant, and a chelating agent (provided that compounds included in the component A, the component B and the component C are excluded).

### (Nitrogen-Containing Heteroaromatic Compound)

The nitrogen-containing heteroaromatic compound is not particularly limited as long as it is a compound having a heteroaromatic ring (nitrogen-containing heteroaromatic ring) in which at least one of atoms constituting the ring is a nitrogen atom. The nitrogen-containing heteroaromatic compound serves as an anticorrosive that improves corrosion prevention performance of the cleaning liquid. Accordingly, it is preferable for the cleaning liquid to contain the nitrogen-containing heteroaromatic compound.

The nitrogen-containing heteroaromatic compound is not particularly limited, and examples thereof include an azole compound, a pyridine compound, a pyrazine compound, and a pyrimidine compound.

The azole compound is a compound having a five-membered heterocyclic ring containing at least one nitrogen atom and having aromatic properties. The number of nitrogen atoms included in the five-membered heterocyclic ring of the azole compound is not particularly limited, and is preferably 2 to 4 and more preferably 3 or 4.

The azole compound may have a substituent on the five-membered heterocyclic ring. Examples of the substituent include a hydroxy group, a carboxy group, a mercapto group, an amino group, an alkyl group having 1 to 4 carbon atoms that may have an amino group, and a 2-imidazolyl group.

Examples of the azole compound include an imidazole compound, a pyrazole compound, a thiazole compound, a triazole compound, and a tetrazole compound.

Examples of the imidazole compound include imidazole, 1-methylimidazole, 2-methylimidazole, 5-methylimidazole, 1,2-dimethylimidazole, 2-mercaptoimidazole, 4,5-dimethyl-2-mercaptoimidazole, 4-hydroxyimidazole, 2,2′-biimidazole, 4-imidazolecarboxylic acid, histamine, benzimidazole, 2-aminobenzimidazole, and adenine.

Examples of the pyrazole compound include pyrazole, 4-pyrazolecarboxylic acid, 1-methylpyrazole, 3-methylpyrazole, 3-amino-5-hydroxypyrazole, 3-amino-5-methylpyrazole, 3-aminopyrazole, and 4-aminopyrazole.

Examples of the thiazole compound include 2,4-dimethylthiazole, benzothiazole, and 2-mercaptobenzothiazole.

Examples of the triazole compound include 1,2,4-triazole, 3-methyl-1,2,4-triazole, 3-amino-1,2,4-triazole, 1,2,3-triazole, 1-methyl-1,2,3-triazole, benzotriazole, 1-hydroxybenzotriazole, 1-dihydroxypropylbenzotriazole, 2,3-dicarboxypropylbenzotriazole, 4-hydroxybenzotriazole, 4-carboxybenzotriazole, and 5-methylbenzotriazole.

Examples of the tetrazole compound include 1H-tetrazole(1,2,3,4-tetrazole), 5-methyl-1,2,3,4-tetrazole, 5-amino-1,2,3,4-tetrazole, 1,5-pentamethylenetetrazole, 1-phenyl-5-mercaptotetrazole, and 1-(2-dimethylaminoethyl)-5-mercaptotetrazole.

For the azole compound, the imidazole compound or the pyrazole compound is preferred, and 2-aminobenzimidazole, adenine, pyrazole, or 3-amino-5-methylpyrazole is more preferred.

The pyridine compound is a compound having a six-membered heterocyclic ring (pyridine ring) containing one nitrogen atom and having aromatic properties.

Specific examples of the pyridine compound include pyridine, 3-aminopyridine, 4-aminopyridine, 3-hydroxypyridine, 4-hydroxypyridine, 2-acetamidopyridine, 2-cyanopyridine, 2-carboxypyridine, and 4-carboxypyridine.

The pyrazine compound is a compound having a six-membered heterocyclic ring (pyrazine ring) containing two nitrogen atoms at the para positions and having aromatic properties, and the pyrimidine compound is a compound having a six-membered heterocyclic ring (pyrimidine ring) containing two nitrogen atoms at the meta positions and having aromatic properties.

Examples of the pyrazine compound include pyrazine, 2-methylpyrazine, 2,5-dimethylpyrazine, 2,3,5-trimethylpyrazine, 2,3,5,6-tetramethylpyrazine, 2-ethyl-3-methylpyrazine, and 2-amino-5-methylpyrazine.

Examples of the pyrimidine compound include pyrimidine, 2-methylpyrimidine, 2-aminopyrimidine, and 4,6-dimethylpyrimidine, with 2-aminopyrimidine being preferred.

For the nitrogen-containing heteroaromatic compound, the azole compound or the pyrazine compound is preferred, and the azole compound is more preferred.

The nitrogen-containing heteroaromatic compounds may be used singly or in combination of two or more.

When the cleaning liquid contains the nitrogen-containing heteroaromatic compound, the content of the nitrogen-containing heteroaromatic compound in the cleaning liquid is not particularly limited and is preferably 0.01 to 10 mass % and more preferably 0.05 to 5 mass % based on the total mass of the cleaning liquid.

Further, when the cleaning liquid contains the nitrogen-containing heteroaromatic compound, the content of the nitrogen-containing heteroaromatic compound is preferably 0.1 to 50 mass % and more preferably 0.5 to 30 mass % based on the total mass of components, excluding a solvent, in the cleaning liquid.

### (Reducing Agent)

The reducing agent is a compound having an oxidative effect and having the function of oxidizing OH⁻ ions or dissolved oxygen contained in the cleaning liquid, and is also called an oxygen scavenger. The reducing agent serves as an anticorrosive that improves corrosion prevention performance of the cleaning liquid. Accordingly, it is preferable for the cleaning liquid to contain the reducing agent.

The reducing agent used in the cleaning liquid is not particularly limited, and examples thereof include an ascorbic acid compound, a catechol compound, a hydroxylamine compound, a hydrazide compound, and a reducing sulfur compound.

### —Ascorbic Acid Compound—

The ascorbic acid compound refers to at least one selected from the group consisting of ascorbic acid, an ascorbic acid derivative, and their salts.

Examples of the ascorbic acid derivative include an ascorbic acid phosphoric acid ester and an ascorbic acid sulfuric acid ester.

For the ascorbic acid compound, preferred is ascorbic acid, ascorbic acid phosphoric acid ester, or ascorbic acid sulfuric acid ester, and more preferred is ascorbic acid.

### —Catechol Compound—

The catechol compound refers to at least one selected from the group consisting of pyrocatechol(benzene-1,2-diol) and a catechol derivative.

The catechol derivative refers to a compound of pyrocatechol obtained through substitution with at least one substituent. Examples of the substituent that the catechol derivative has include a hydroxy group, a carboxy group, a carboxylic acid ester group, a sulfo group, a sulfonic acid ester group, an alkyl group (preferably with 1 to 6 carbon atoms and more preferably with 1 to 4 carbon atoms), and an aryl group (preferably a phenyl group). The carboxy group and the sulfo group that the catechol derivative has as substituents may be salts of a cation. The alkyl group and the aryl group that the catechol derivative has as substituents may further have a substituent.

Examples of the catechol compound include pyrocatechol, 4-tert-butylcatechol, pyrogallol, gallic acid, methyl gallate, 1,2,4-benzenetriol, and tiron.

### —Hydroxylamine Compound—

The hydroxylamine compound refers to at least one selected from the group consisting of a hydroxylamine (NH₂OH), a hydroxylamine derivative, and their salts. The hydroxylamine derivative refers to a compound of hydroxylamine (NH₂OH) obtained through substitution with at least one organic group.

A salt of the hydroxylamine or the hydroxylamine derivative may be an inorganic or organic acid salt of the hydroxylamine or the hydroxylamine derivative. For the salt of the hydroxylamine or the hydroxylamine derivative, preferred is a salt thereof with an inorganic acid in which at least one non-metal selected from the group consisting of Cl, S, N and P is bonded to hydrogen, and more preferred is a hydrochloride, a sulfate, or a nitrate.

Examples of the hydroxylamine compound include a compound represented by Formula (1) below or its salt.

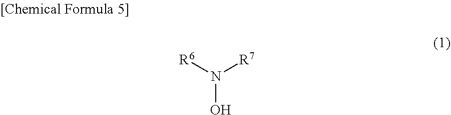

In Formula (1), R⁶ and R⁷ each independently represent a hydrogen atom or an organic group.

For the organic group represented by R⁶ and R⁷, an alkyl group having 1 to 6 carbon atoms is preferred. The alkyl group having 1 to 6 carbon atoms may be any of linear, branched and cyclic groups.

At least one of R⁶ and R⁷ is preferably an organic group (more preferably, an alkyl group having 1 to 6 carbon atoms).

For the alkyl group having 1 to 6 carbon atoms, an ethyl group or an n-propyl group is preferred, and an ethyl group is more preferred.

Examples of the hydroxylamine compound include hydroxylamine, O-methylhydroxylamine, O-ethylhydroxylamine, N-methylhydroxylamine, N,N-dimethylhydroxylamine, N,O-dimethylhydroxylamine, N-ethylhydroxylamine, N,N-diethylhydroxylamine, N,O-diethylhydroxylamine, O,N,N-trimethylhydroxylamine, N,N-dicarboxyethylhydroxylamine, and N,N-disulfoethylhydroxylamine.

Of these, N-ethylhydroxylamine, N,N-diethylhydroxylamine (DEHA), or N-n-propylhydroxylamine is preferred, and DEHA is more preferred.

### —Hydrazide Compound—

The hydrazide compound refers to a compound obtained by substituting a hydroxy group of an acid with a hydrazino group (—NH—NH₂), as well as its derivative (a compound with a hydrazino group having at least one substituent).

The hydrazide compound may have two or more hydrazino groups.

Examples of the hydrazide compound include carboxylic acid hydrazide and sulfonic acid hydrazide, with carbohydrazide (CHZ) being preferred.

### —Reducing Sulfur Compound—

The reducing sulfur compound is not particularly limited as long as it contains a sulfur atom and functions as the reducing agent, and examples thereof include mercaptosuccinic acid, dithiodiglycerol, bis(2,3-dihydroxypropylthio)ethylene, sodium 3-(2,3-dihydroxypropylthio)-2-methyl-propylsulfonate, 1-thioglycerol, sodium 3-mercapto-1-propanesulfonate, 2-mercaptoethanol, thioglycolic acid, and 3-mercapto-1-propanol.

Of these, a compound having an SH group (mercapto compound) is preferred, and 1-thioglycerol, sodium 3-mercapto-1-propanesulfonate, 2-mercaptoethanol, 3-mercapto-1-propanol, or thioglycolic acid is more preferred.

For the reducing agent, the ascorbic acid compound or the hydroxylamine compound is preferred, and the ascorbic acid compound is more preferred.

The reducing agents may be used singly or in combination of two or more. The cleaning liquid preferably contains two or more reducing agents because this leads to more excellent corrosion prevention performance (particularly with respect to a W-containing metal film).

When the cleaning liquid contains the reducing agent, the reducing agent content is not particularly limited and is preferably 0.01 to 20 mass % and more preferably 0.1 to 5 mass % based on the total mass of the cleaning liquid.

Further, when the cleaning liquid contains the reducing agent, the reducing agent content is preferably 0.1 to 50 mass % and more preferably 0.5 to 30 mass % based on the total mass of components, excluding a solvent, in the cleaning liquid.

Those reducing agents for use may be commercial products or composites synthesized by a known method.

### (Anionic Surfactant)

The anionic surfactant is a compound having an anionic hydrophilic group and a hydrophobic group (lipophilic group) in the molecule.

Examples of the anionic surfactant contained in the cleaning liquid include a phosphoric acid ester-based surfactant having a phosphoric acid ester group, a phosphonic acid-based surfactant having a phosphonic acid group, a sulfonic acid-based surfactant having a sulfo group, a carboxylic acid-based surfactant having a carboxy group, and a sulfuric acid ester-based surfactant having a sulfuric acid ester group, with those groups each acting as a hydrophilic group (acid group).

Those anionic surfactants not only improve cleaning performance but also serve as anticorrosives that improve corrosion prevention performance (particularly with respect to a Co- and/or Cu-containing metal film). Accordingly, it is preferable for the cleaning liquid to contain the anionic surfactant.

### —Phosphoric Acid Ester-Based Surfactant—

Examples of the phosphoric acid ester-based surfactant include phosphoric acid ester (alkyl ether phosphoric acid ester), polyoxyalkylene ether phosphoric acid ester, and salts thereof. While the phosphoric acid ester and the polyoxyalkylene ether phosphoric acid ester usually include both a monoester and a diester, a monoester or a diester may be used alone.

Examples of the salts of the phosphoric acid ester-based surfactant include a sodium salt, a potassium salt, an ammonium salt, and an organic amine salt.

A monovalent alkyl group that the phosphoric acid ester and the polyoxyalkylene ether phosphoric acid ester have is not particularly limited and is preferably an alkyl group having 2 to 24 carbon atoms, more preferably an alkyl group having 6 to 18 carbon atoms, and even more preferably an alkyl group having 12 to 18 carbon atoms.

A divalent alkylene group that the polyoxyalkylene ether phosphoric acid ester has is not particularly limited and is preferably an alkylene group having 2 to 6 carbon atoms and more preferably an ethylene group or a 1,2-propanediyl group. The number of repeats of an oxyalkylene group in the polyoxyalkylene ether phosphoric acid ester is preferably 1 to 12 and more preferably 3 to 10.

For the phosphoric acid ester-based surfactant, preferred is octyl phosphoric acid ester, lauryl phosphoric acid ester, tridecyl phosphoric acid ester, myristyl phosphoric acid ester, cetyl phosphoric acid ester, stearyl phosphoric acid ester, polyoxyethylene octyl ether phosphoric acid ester, polyoxyethylene lauryl ether phosphoric acid ester, or polyoxyethylene tridecyl ether phosphoric acid ester.

For the phosphoric acid ester-based surfactant, the compounds described in paragraphs [0012] to [0019] of JP 2011-040502 A can also be applied, and the contents thereof are incorporated in the present specification.

### —Phosphonic Acid-Based Surfactant—

Examples of the phosphonic acid-based surfactant include alkyl phosphonic acid and polyvinyl phosphonic acid as well as aminomethyl phosphonic acid described in, for example, JP 2012-057108 A.

### —Sulfonic Acid-Based Surfactant—

Examples of the sulfonic acid-based surfactant include alkyl sulfonic acid, alkylbenzene sulfonic acid, alkylnaphthalene sulfonic acid, alkyl diphenyl ether disulfonic acid, alkyl methyl taurine, sulfosuccinic acid diester, polyoxyalkylene alkyl ether sulfonic acid, and salts thereof.

A monovalent alkyl group that the sulfonic acid-based surfactant has is not particularly limited and is preferably an alkyl group having 10 or more carbon atoms and more preferably an alkyl group having 12 or more carbon atoms. The upper limit thereof is not particularly limited and is preferably not more than 24.

A divalent alkylene group that the polyoxyalkylene alkyl ether sulfonic acid has is not particularly limited and is preferably an ethylene group or a 1,2-propanediyl group. The number of repeats of an oxyalkylene group in the polyoxyalkylene alkyl ether sulfonic acid is preferably 1 to 12 and more preferably 1 to 6.

Specific examples of the sulfonic acid-based surfactant include hexanesulfonic acid, octanesulfonic acid, decanesulfonic acid, dodecanesulfonic acid, toluenesulfonic acid, cumenesulfonic acid, octylbenzenesulfonic acid, dodecylbenzenesulfonic acid (DBSA), dinitrobenzenesulfonic acid (DNBSA), and lauryl dodecylphenyl ether disulfonic acid (LDPEDSA).

In particular, a sulfonic acid-based surfactant with an alkyl group having 10 or more carbon atoms is preferred, a sulfonic acid-based surfactant with an alkyl group having 12 or more carbon atoms is more preferred, and DBSA is even more preferred.

### —Carboxylic Acid-Based Surfactant—

Examples of the carboxylic acid-based surfactant include alkyl carboxylic acid, alkylbenzene carboxylic acid, and polyoxyalkylene alkyl ether carboxylic acid, and salts thereof.

A monovalent alkyl group that the carboxylic acid-based surfactant has is not particularly limited and is preferably an alkyl group having 7 to 25 carbon atoms and more preferably an alkyl group having 11 to 17 carbon atoms.

A divalent alkylene group that the polyoxyalkylene alkyl ether carboxylic acid has is not particularly limited and is preferably an ethylene group or a 1,2-propanediyl group. The number of repeats of an oxyalkylene group in the polyoxyalkylene alkyl ether carboxylic acid is preferably 1 to 12 and more preferably 1 to 6.

Specific examples of the carboxylic acid-based surfactant include lauric acid, myristic acid, palmitic acid, stearic acid, polyoxyethylene lauryl ether acetic acid, and polyoxyethylene tridecyl ether acetic acid.

### —Sulfuric Acid Ester-Based Surfactant—

Examples of the sulfuric acid ester-based surfactant include sulfuric acid ester (alkyl ether sulfuric acid ester), polyoxyalkylene ether sulfuric acid ester, and salts thereof.

A monovalent alkyl group that the sulfuric acid ester and the polyoxyalkylene ether sulfuric acid ester have is not particularly limited and is preferably an alkyl group having 2 to 24 carbon atoms and more preferably an alkyl group having 6 to 18 carbon atoms.

A divalent alkylene group that the polyoxyalkylene ether sulfuric acid ester has is not particularly limited and is preferably an ethylene group or a 1,2-propanediyl group. The number of repeats of an oxyalkylene group in the polyoxyalkylene ether sulfuric acid ester is preferably 1 to 12 and more preferably 1 to 6.

Specific examples of the sulfuric acid ester-based surfactant include lauryl sulfuric acid ester, myristyl sulfuric acid ester, and polyoxyethylene lauryl ether sulfuric acid ester.

For the anionic surfactant, preferred is at least one selected from the group consisting of the phosphoric acid ester-based surfactant, the sulfonic acid-based surfactant (more preferably, a sulfonic acid-based surfactant with an alkyl group having 12 or more carbon atoms), the phosphonic acid-based surfactant, and the carboxylic acid-based surfactant, and more preferred is the phosphoric acid ester-based surfactant, a sulfonic acid-based surfactant with an alkyl group having 12 or more carbon atoms, or the phosphonic acid ester-based surfactant.

The anionic surfactants may be used singly or in combination of two or more. The cleaning liquid preferably contains two or more anionic surfactants because this leads to more excellent corrosion prevention performance (particularly with respect to a Cu- and/or Co-containing metal film).

When the cleaning liquid contains the anionic surfactant, the content thereof is preferably 0.01 to 5.0 mass % and more preferably 0.05 to 2.0 mass % based on the total mass of the cleaning liquid.

Further, when the cleaning liquid contains the anionic surfactant, the content thereof is preferably 0.05 to 50 mass % and more preferably 0.5 to 30 mass % based on the total mass of components, excluding a solvent, in the cleaning liquid.

Commercial products may be used as those anionic surfactants.

### (Chelating Agent)

The cleaning liquid may contain a chelating agent.

The chelating agent used in the cleaning liquid is a compound that has a function of chelating with metal contained in a residue in a cleaning step of a semiconductor substrate. In particular, a compound having in the molecule two or more functional groups (coordination groups) that form coordinate bonds with a metal ion.

In the present specification, compounds included in the component A, the component B and the component C described above are not included in the chelating agent.

It is preferable for the cleaning liquid to contain the chelating agent because this leads to excellent cleaning performance and corrosion prevention performance.

Examples of the chelating agent include an organic chelating agent and an inorganic chelating agent.

The organic chelating agent is a chelating agent constituted of an organic compound, and examples thereof include a hydroxy carboxylic acid-based chelating agent, an aliphatic carboxylic acid-based chelating agent, and a compound having at least two nitrogen-containing groups (groups each containing a nitrogen atom) and having no carboxyl group (hereinafter also called “specific nitrogen-containing chelating agent”).

Examples of the inorganic chelating agent include condensed phosphoric acid and salts thereof.

For the chelating agent, the organic chelating agent is preferred, and a hydroxy carboxylic acid-based chelating agent is more preferred.

Examples of the hydroxy carboxylic acid-based chelating agent include malic acid, citric acid, glycolic acid, gluconic acid, heptonic acid, tartaric acid, and lactic acid, with preferred being gluconic acid, glycolic acid, malic acid, tartaric acid, or citric acid, and more preferred being gluconic acid or citric acid.

Examples of the aliphatic carboxylic acid-based chelating agent include oxalic acid, malonic acid, succinic acid, glutaric acid, adipic acid, pimelic acid, sebacic acid, and maleic acid, with adipic acid being preferred. In particular, the use of an adipic acid allows performance (cleaning performance and corrosion prevention performance) of the cleaning liquid to greatly improve as compared to other chelating agents. Although the precise mechanism of such a distinctive effect of an adipic acid is unclear, the mechanism is assumed to be derived from the fact that an adipic acid has particularly excellent hydrophilicity and hydrophobicity due to the relationship between the number of carbon atoms of an alkylene group and two carboxy groups and therefore forms a stable ring structure in formation of a complex with metal.

The hydroxy carboxylic acid-based chelating agent and the aliphatic carboxylic acid-based chelating agent are preferably of low molecular weight. Specifically, the molecular weights of those chelating agents are each preferably not more than 600, more preferably not more than 450 and even more preferably not more than 300. The lower limit thereof is not particularly limited and is preferably not less than 85.

The number of carbon atoms in each of the hydroxy carboxylic acid-based chelating agent and the aliphatic carboxylic acid-based chelating agent is preferably not more than 15, more preferably not more than 12 and even more preferably not more than 8. The lower limit thereof is not particularly limited and is preferably not less than 2.

Examples of the specific nitrogen-containing chelating agent include at least one biguanide compound selected from the group consisting of a biguanide group-containing compound and a salt thereof.

The number of biguanide groups that the biguanide compound has is not particularly limited and may be plural.

For the biguanide compound, the compounds described in paragraphs [0034] to [0055] of JP 2017-504190 A can be applied, and the contents thereof are incorporated in the present specification.

For the biguanide group-containing compound, preferred is ethylene dibiguanide, propylene dibiguanide, tetramethylene dibiguanide, pentamethylene dibiguanide, hexamethylene dibiguanide, heptamethylene dibiguanide, octamethylene dibiguanide, 1,1′-hexamethylenebis(5-(p-chlorophenyl)biguanide) (chlorhexidine), 2-(benzyloxymethyl)pentane-1,5-bis(5-hexylbiguanide), 2-phenylthiomethyl)pentane-1,5-bis(5-phenethylbiguanide), 3-(phenylthio)hexane-1,6-bis(5-hexylbiguanide), 3-(phenylthio)hexane-1,6-bis(5-cyclohexylbiguanide), 3-(benzylthio)hexane-1,6-bis(5-hexylbiguanide), or 3-(benzylthio)hexane-1,6-bis(5-cyclohexylbiguanide), and more preferred is chlorhexidine.

For the salt of the biguanide group-containing compound, a hydrochloride, an acetate, or a gluconate is preferred.

Examples of the condensed phosphoric acid and salts thereof which are the inorganic chelating agents include pyrophosphoric acid and salts thereof, metaphosphoric acid and salts thereof, tripolyphosphoric acid and salts thereof, and hexametaphosphoric acid and salts thereof.

For the chelating agent, preferred is the hydroxy carboxylic acid-based chelating agent, the aliphatic carboxylic acid-based chelating agent, or the biguanide compound, more preferred is gluconic acid, glycolic acid, malic acid, tartaric acid, citric acid, adipic acid, or chlorhexidine or its salt, and even more preferred is gluconic acid, citric acid, adipic acid, or chlorhexidine or its salt.

The chelating agents may be used singly or in combination of two or more.

When the cleaning liquid contains the chelating agent, the chelating agent content of the cleaning liquid is not particularly limited and is preferably not less than 0.01 mass % and more preferably not less than 0.05 mass % based on the total mass of the cleaning liquid because this leads to excellent corrosion prevention performance (particularly with respect to a Cu- and/or Co-containing metal film). The upper limit thereof is not particularly limited and is preferably not more than 3 mass % and more preferably not more than 2 mass % based on the total mass of the cleaning liquid.

Further, when the cleaning liquid contains the chelating agent, the chelating agent content is preferably 0.1 to 30 mass % and more preferably 0.5 to 20 mass % based on the total mass of components, excluding a solvent, in the cleaning liquid.

The components D may be used singly or in combination of two or more.

When the cleaning liquid contains the component D, the component D content is not particularly limited and is preferably not less than 0.01 mass %, more preferably not less than 0.05 mass % and even more preferably not less than 0.1 mass % based on the total mass of the cleaning liquid. The upper limit of the component D content is not particularly limited and is preferably not more than 10.0 mass %, more preferably not more than 5.0 mass % and even more preferably not more than 3.0 mass % based on the total mass of the cleaning liquid.

Further, when the cleaning liquid contains the component D, the component D content is preferably not less than 0.05 mass %, more preferably not less than 0.3 mass % and even more preferably not less than 0.5 mass % based on the total mass of components, excluding a solvent, in the cleaning liquid. The upper limit thereof is not particularly limited and is preferably not more than 80 mass %, more preferably not more than 50 mass % and even more preferably not more than 30 mass % based on the total mass of components, excluding a solvent, in the cleaning liquid.

When the cleaning liquid contains the component D, the mass ratio of the component D content to the sum of the component A content and the component B content (component D content/(component A content+component B content)) is preferably not more than 200, more preferably not more than 100 and even more preferably not more than 20 because this leads to excellent cleaning performance (particularly with respect to a Cu- and/or Co-containing metal film). The lower limit of the above mass ratio is not particularly limited and is preferably not less than 0.1 and more preferably not less than 0.3 because this leads to excellent corrosion prevention performance (particularly with respect to a Cu- and/or Co-containing metal film).

### <Quaternary Ammonium Compound>

The cleaning liquid may contain a quaternary ammonium compound.

The quaternary ammonium compound is not particularly limited as long as it is a quaternary ammonium cation-containing compound in which a nitrogen atom is attached to four hydrocarbon groups (preferably, alkyl groups) through substitution, or a salt thereof. Examples of the quaternary ammonium compound include quaternary ammonium hydroxide, quaternary ammonium fluoride, quaternary ammonium bromide, quaternary ammonium iodide, quaternary ammonium acetate, and quaternary ammonium carbonate.

It is preferable for the cleaning liquid to contain the quaternary ammonium compound because this leads to more excellent corrosion prevention performance (particularly with respect to a Cu- and/or Co-containing metal film).

For the quaternary ammonium compound, preferred is quaternary ammonium hydroxide represented by Formula (2):

(R⁸)₄N⁺OH⁻ (2)

where R⁸ represents an alkyl group that may have a hydroxy group or a phenyl group as a substituent. Four R⁸s may be the same or different.

For the alkyl group represented by R⁸, an alkyl group having 1 to 4 carbon atoms is preferred, and a methyl group or an ethyl group is more preferred.

For the alkyl group that may have a hydroxy group or a phenyl group as represented by R⁸, preferred is a methyl group, an ethyl group, a propyl group, a butyl group, a 2-hydroxyethyl group, or a benzyl group, more preferred is a methyl group, an ethyl group, a propyl group, a butyl group, or a 2-hydroxyethyl group, and even more preferred is a methyl group, an ethyl group, or a 2-hydroxyethyl group.

Examples of the quaternary ammonium compound include tetramethylammonium hydroxide (TMAH), trimethylethylammonium hydroxide (TMEAH), diethyldimethylammonium hydroxide (DEDMAH), methyltriethylammonium hydroxide (MTEAH), tetraethylammonium hydroxide (TEAH), tetrapropylammonium hydroxide (TPAH), tetrabutylammonium hydroxide (TBAH), 2-hydroxyethyl trimethylammonium hydroxide (choline), bis(2-hydroxyethyl)dimethylammonium hydroxide, tri(2-hydroxyethyl)methylammonium hydroxide, tetra(2-hydroxyethyl)ammonium hydroxide, benzyltrimethylammonium hydroxide (BTMAH), and cetyltrimethylammonium hydroxide.

As the quaternary ammonium compound other than the foregoing specific examples, the compounds described in paragraph [0021] of JP 2018-107353 A can be applied, and the contents thereof are incorporated in the present specification.

For the quaternary ammonium compound used for the cleaning liquid, TMAH, TMEAH, DEDMAH, MTEAH, TEAH, TPAH, TBAH, choline, or bis(2-hydroxyethyl)dimethylammonium hydroxide is preferred, and MTEAH is more preferred.

It is preferable for the cleaning liquid to contain a quaternary ammonium compound having an asymmetric structure because this leads to excellent corrosion prevention performance (particularly with respect to a Cu- and/or Co-containing metal film). The quaternary ammonium compound “having an asymmetric structure” means that four hydrocarbon groups attached to a nitrogen atom through substitution are different from one another.

Examples of the quaternary ammonium compound having an asymmetric structure include TMEAH, DEDMAH, MTEAH, choline, and bis(2-hydroxyethyl)dimethylammonium hydroxide, with MTEAH being preferred.

The quaternary ammonium compounds may be used singly or in combination of two or more. It is preferable for the cleaning liquid to contain two or more quaternary ammonium compounds because this leads to more excellent cleaning performance (particularly with respect to a Cu- and/or Co-containing metal film).

When the cleaning liquid contains the quaternary ammonium compound, the content thereof is preferably not less than 0.05 mass %, more preferably not less than 0.1 mass % and even more preferably not less than 0.2 mass % based on the total mass of the cleaning liquid because this leads to more excellent cleaning performance. The upper limit of the quaternary ammonium compound content is not particularly limited and is preferably not more than 10 mass %, more preferably not more than 5 mass % and even more preferably not more than 3 mass % because this can suppress a decrease in cleaning performance that may be caused by agglomeration of residue particles and/or readsorption of residues in a cleaning step.

Further, when the cleaning liquid contains the quaternary ammonium compound, the content thereof is preferably 0.2 to 30 mass % and more preferably 0.5 to 15 mass % based on the total mass of components, excluding a solvent, in the cleaning liquid.

### <Other Surfactants>

The cleaning liquid may contain a surfactant other than the anionic surfactant.

Other surfactants are not particularly limited as long as they are compounds different from the anionic surfactant and having a hydrophilic group and a hydrophobic group (lipophilic group) in the molecule, and examples thereof include a cationic surfactant, a nonionic surfactant, and an amphoteric surfactant.

In many cases, the surfactant has a hydrophobic group selected from an aliphatic hydrocarbon group, an aromatic hydrocarbon group, and combinations thereof. The hydrophobic group that the surfactant has is not particularly limited; when the hydrophobic group contains an aromatic hydrocarbon group, the number of carbon atoms is preferably 6 or more and more preferably 10 or more. When the hydrophobic group contains no aromatic hydrocarbon group and is constituted only of an aliphatic hydrocarbon group, the number of carbon atoms is preferably 10 or more, more preferably 12 or more, and even more preferably 16 or more. The upper limit of the number of carbon atoms of the hydrophobic group is not particularly limited and is preferably not more than 20 and more preferably not more than 18.

### (Cationic Surfactant)

Examples of the cationic surfactant include primary to tertiary alkylamine salts (e.g., monostearyl ammonium chloride, distearyl ammonium chloride, and tristearyl ammonium chloride), and modified aliphatic polyamine (e.g., polyethylene polyamine).

### (Nonionic Surfactant)

Examples of the nonionic surfactant include polyoxyalkylene alkyl ether (e.g., polyoxyethylene stearyl ether), polyoxyalkylene alkenyl ether (e.g., polyoxyethylene oleyl ether), polyoxyethylene alkyl phenyl ether (e.g., polyoxyethylene nonyl phenyl ether), polyoxyalkylene glycol (e.g., polyoxypropylene polyoxyethylene glycol), polyoxyalkylene monoalkylate (monoalkyl fatty acid ester polyoxyalkylene) (e.g., polyoxyethylene monoalkylates such as polyoxyethylene monostearate and polyoxyethylene monooleate), polyoxyalkylene dialkylate (dialkyl fatty acid ester polyoxyalkylene) (e.g., polyoxyethylene dialkylates such as polyoxyethylene distearate and polyoxyethylene dioleate), bispolyoxyalkylene alkylamide (e.g., bispolyoxyethylene stearylamide), sorbitan fatty acid ester, polyoxyethylene sorbitan fatty acid ester, polyoxyethylene alkylamine, glycerine fatty acid ester, oxyethylene-oxypropylene block copolymer, acetylene glycol-based surfactant, and acetylene-based polyoxyethylene oxide.

### (Amphoteric Surfactant)

Examples of the amphoteric surfactant include carboxy betaine (e.g., alkyl-N,N-dimethylaminoacetic acid betaine and alkyl-N,N-dihydroxyethylaminoacetic acid betaine), sulfo betaine (e.g., alkyl-N,N-dimethylsulfoethylene ammonium betaine), and imidazolinium betaine (e.g., 2-alkyl-N-carboxymethyl-N-hydroxyethylimidazolinium betaine).

For the surfactant, the compounds described in paragraphs [0092] to [0096] of JP 2015-158662 A, paragraphs [0045] to [0046] of JP 2012-151273 A, and paragraphs [0014] to [0020] of JP 2009-147389 A can also be applied, and the contents thereof are incorporated in the present specification.

### <Additives>

The cleaning liquid may optionally contain other additives than the foregoing components. Examples of such additives include a pH adjuster, an anticorrosive (excluding components included in the component D), a polymer, a fluorine compound, and an organic solvent.

### (pH Adjuster)

The cleaning liquid may contain a pH adjuster for adjusting and maintaining the pH of the cleaning liquid. Examples of the pH adjuster include a basic compound and an acidic compound other than the foregoing components.

Examples of the basic compound include a basic organic compound and a basic inorganic compound.

The basic organic compound is a basic organic compound different from the foregoing components. Examples of the basic organic compound include amine oxide, nitro, nitroso, oxime, ketoxime, aldoxime, lactam, isocyanide compounds, and urea.

Examples of the basic inorganic compound include alkali metal hydroxide, alkaline earth metal hydroxide, and ammonia.

Examples of the alkali metal hydroxide include lithium hydroxide, sodium hydroxide, potassium hydroxide, and cesium hydroxide. Examples of the alkaline earth metal hydroxide include calcium hydroxide, strontium hydroxide, and barium hydroxide.

Any of compounds contained as the component A, the component B, the component C, and/or the component D described above may also serve as the basic compound for increasing the pH of the cleaning liquid.

Those basic compounds for use may be commercial products or composites suitably synthesized by a known method.

Examples of the acidic compound include an inorganic acid and an organic acid.

Examples of the inorganic acid include hydrochloric acid, sulfuric acid, sulfurous acid, nitric acid, nitrous acid, phosphoric acid, boric acid, and hexafluorophosphoric acid. Salts of the inorganic acids may also be used, and examples thereof include ammonium salts of the inorganic acids, more specifically, ammonium chloride, ammonium sulfate, ammonium sulfite, ammonium nitrate, ammonium nitrite, ammonium phosphate, ammonium borate, and ammonium hexafluorophosphate.

For the inorganic acid, phosphoric acid or phosphate is preferred, and phosphoric acid is more preferred.

The organic acid is an organic compound having an acidic functional group and showing acidic properties (pH: less than 7.0) in an aqueous solution and is a compound that is not included in the chelating agent or the anionic surfactant described above. Examples of the organic acid include lower aliphatic monocarboxylic acids (with 1 to 4 carbon atoms) such as formic acid, acetic acid, propionic acid and butyric acid.

As the acidic compound, a salt of the acidic compound may be used as long as it forms an acid or an acid ion (anion) in an aqueous solution.

The chelating agent and/or anionic surfactant contained in the cleaning liquid may also serve as the acidic compound for reducing the pH of the cleaning liquid.

As the acidic compound, a commercial product or a composite suitably synthesized by a known method may be used.

The pH adjusters may be used singly or in combination of two or more.

When the cleaning liquid contains the pH adjuster, the content thereof is selected depending on the types and amounts of other components and the pH of a target cleaning liquid, and is preferably 0.01 to 3 mass % and more preferably 0.05 to 1 mass % based on the total mass of the cleaning liquid.

Further, when the cleaning liquid contains the pH adjuster, the content thereof is selected depending on the types and amounts of other components and the pH of a target cleaning liquid, and is preferably 0.05 to 10 mass % and more preferably 0.2 to 5 mass % based on the total mass of components, excluding a solvent, in the cleaning liquid.

The cleaning liquid may contain another anticorrosive different from the foregoing components.

Examples of such another anticorrosive include sugars such as fructose, glucose, and ribose, polyol compounds such as ethylene glycol, propylene glycol, and glycerin, polycarboxylic acid compounds such as polyacrylic acid, polymaleic acid, and copolymers thereof, polyvinylpyrrolidone, cyanuric acid, barbituric acid and its derivatives, glucuronic acid, squaric acid, α-keto acid, adenosine and its derivatives, a purine compound and its derivatives, phenanthroline, resorcinol, hydroquinone, nicotinamide and its derivatives, flavonol and its derivatives, anthocyanin and its derivatives, and combinations thereof.

For the polymer, the water-soluble polymers described in paragraphs [0043] to [0047] of JP 2016-171294 A can be applied, and the contents thereof are incorporated in the present specification.

For the fluorine compound, the compounds described in paragraphs [0013] to [0015] of JP 2005-150236 A can be applied, and the contents thereof are incorporated in the present specification.

For the organic solvent, any of known organic solvents may be used, and hydrophilic organic solvents such as alcohols and ketones are preferred. The organic solvents may be used singly or in combination of two or more.

The amounts of the polymer, fluorine compound and organic solvent for use are not particularly limited and may be suitably specified in the ranges that do not impair the effects of the invention.

The contents of the respective components above in the cleaning liquid can be measured by known methods such as gas chromatography-mass spectrometry (GC-MS), liquid chromatography-mass spectrometry (LC-MS), and ion-exchange chromatography (IC).

### [Physical Properties of Cleaning Liquid]

<pH>

The cleaning liquid preferably shows alkaline properties. Specifically, the pH of the cleaning liquid is preferably more than 7.0 at 25° C.

The pH of the cleaning liquid is more preferably not less than 8.0, and in terms of providing more excellent cleaning performance and corrosion prevention performance (particularly corrosion prevention performance with respect to a Co- and/or Cu-containing metal film), even more preferably more than 8.5, and particularly preferably not less than 9.0 at 25° C. The upper limit of the pH of the cleaning liquid is not particularly limited and is preferably not more than 12.0, and in terms of providing more excellent corrosion prevention performance (particularly with respect to a W- and/or Cu-containing metal film), more preferably less than 11.5, and even more preferably not more than 11.0 at 25° C.

The pH of the cleaning liquid may be adjusted by using the foregoing pH adjusters as well as components functioning as the pH adjuster, such as the component A, the component B, the component C, the component D, and the quaternary ammonium compound as above.

The pH of the cleaning liquid can be measured with a known pH meter by the method according to JIS Z 8802-1984.

### <Metal Content>

In the cleaning liquid, the content of each of metals (elemental metals Fe, Co, Na, K, Cu, Mg, Mn, Li, Al, Cr, Ni, Zn, Sn and Ag) contained as impurities in the liquid (calculated as the ion concentration) is preferably not more than 5 ppm by mass and more preferably not more than 1 ppm by mass. Since it is expected in manufacture of leading-edge semiconductor devices that a cleaning liquid with even higher purity should be required, the metal content is still more preferably less than 1 ppm by mass, that is, a value on the order of ppb by mass or less, particularly preferably 100 ppb by mass or less, and most preferably less than 10 ppb by mass. The lower limit thereof is not particularly limited and is preferably 0.

Exemplary methods of reducing the metal content include a refining treatment, such as distillation or filtration using ion-exchange resin or a filter, that is carried out in a stage of raw materials to be used in manufacture of the cleaning liquid or a stage after manufacture of the cleaning liquid.

Another method of reducing the metal content is the one using, as a container storing a raw material or the manufactured cleaning liquid, a container from which impurities are not largely leached, which will be described later. Still another method is providing lining of fluororesin on the portions of members that are to contact the relevant liquid, such as inner walls of pipes used in manufacture of the cleaning liquid, in order to prevent metal components from being leached from the members such as the pipes.

### <Coarse Particles>

The cleaning liquid may contain coarse particles but preferably in a small amount. The coarse particles herein refer to particles with a diameter (particle size) of 0.4 μm or more when the particle shape is assumed to be a sphere.

For the coarse particle content of the cleaning liquid, the content of particles with a particle size of 0.4 μm or more is preferably not more than 1000 particles and more preferably not more than 500 particles per milliliter of the cleaning liquid. The lower limit thereof is not particularly limited and is for instance 0. The content of particles with a particle size of 0.4 μm or more measured by one of the foregoing measurement methods is even more preferably at or below the detection limit.

The coarse particles contained in the cleaning liquid are particles of dust, dirt, organic and inorganic solid matter, and the like contained as impurities in raw materials and particles of dust, dirt, organic and inorganic solid matter, and the like entering as contaminations during preparation of the cleaning liquid, which particles remain present as particles in the cleaning liquid at the end without being dissolved.

The content of the coarse particles present in the cleaning liquid can be measured in a liquid phase with a commercial measurement device for a light scattering liquid-borne particle counting method using a laser as a light source.

One exemplary method of removing the coarse particles is a refining treatment such as filtration to be described later.

The cleaning liquid may take the form of a kit including raw materials of the cleaning liquid that are separated into plural units.

One exemplary method of having the cleaning liquid in the form of a kit involves preparing a liquid composition containing the component A and the component B as a first liquid and preparing a liquid composition containing the component C and the other components as a second liquid.

### [Manufacture of Cleaning Liquid]

The cleaning liquid can be manufactured by a known method. The method of manufacturing the cleaning liquid is described below in detail.

### <Liquid Preparation Step>

The method of preparing the cleaning liquid is not particularly limited, and for instance, the cleaning liquid can be manufactured by mixing the foregoing components. The order and/or timing of incorporating the foregoing components are not particularly limited; for instance, the component A, the component B and the component C as well as the component D and the quaternary ammonium compound as optional components are sequentially added into a vessel containing purified pure water and then stirred and mixed, while the pH adjuster is added to adjust the pH of the mixture, thereby preparing the cleaning liquid. When added to the vessel, water and those components may be added at one time or may be divided into plural portions and separately added.

A stirrer and a stirring method used in preparation of the cleaning liquid are not particularly limited, and a known device may be used as the stirrer or a disperser. Examples of the stirrer include an industrial mixer, a portable stirrer, a mechanical stirrer, and a magnetic stirrer. Examples of the disperser include an industrial disperser, a homogenizer, an ultrasonic disperser, and a bead mill.

Mixing of the components in the preparation step of the cleaning liquid, a refining treatment to be described later, and storage of the manufactured cleaning liquid are carried out at a temperature of preferably not higher than 40° C. and more preferably not higher than 30° C. At the same time, not lower than 5° C. is preferred, and not lower than 10° C. is more preferred. The preparation, the treatment and/or the storage of the cleaning liquid within the above temperature range makes it possible to maintain stable performance for a long period of time.

### (Refining Treatment)

One or more of raw materials used in preparation of the cleaning liquid is preferably subjected to a refining treatment in advance. The refining treatment is not particularly limited, and examples thereof include known methods such as distillation, ion exchange, and filtration.

The degree of refining is not particularly limited, and a raw material is refined to a purity of preferably not less than 99 mass % and more preferably not less than 99.9 mass %.

Examples of specific methods of the refining treatment include a method in which a raw material is passed through ion-exchange resin or a reverse osmosis membrane (RO membrane), distillation of a raw material, and filtration to be described later.

As the refining treatment, the foregoing refining methods may be used in combination of two or more. For instance, a raw material may be firstly subjected to primary refinement in which the material is passed through a RO membrane and then to secondary refinement in which the material is passed through a refinement device made of cation exchange resin, anion exchange resin, or mixed-bed ion exchange resin. The refining treatment may be carried out plural times.

### (Filtration)

A filter used in filtration is not particularly limited as long as it is of a type that has been conventionally used for filtration. Examples of the filter include filters made of fluororesins such as polytetrafluoroethylene (PTFE) and tetrafluoroethylene-perfluoroalkylvinylether copolymer (PFA), polyamide resins such as nylon, and polyolefin resins (including high density ones and ultra high molecular weight ones) such as polyethylene and polypropylene (PP). Preferred is a filter made of, of the above materials, a material selected from the group consisting of polyethylene, polypropylene (including high density polypropylene), fluororesin (including PTFE and PFA), and polyamide resin (including nylon), and more preferred is a filter made of fluororesin. By filtering a raw material with the filter made of such a material, foreign matter with high polarity that easily causes defects can be effectively removed.

The filter has a critical surface tension of preferably 70 to 95 mN/m and more preferably 75 to 85 mN/m. It should be noted that the value of the critical surface tension of the filter is a nominal value provided by its manufacturer. The use of the filter having a critical surface tension within the above range makes it possible to effectively remove foreign matter with high polarity that easily causes defects.

The filter has a pore size of preferably 2 to 20 nm and more preferably 2 to 15 nm. The pore size within the above range makes it possible to reliably remove fine foreign matter such as impurities and agglomerates contained in a raw material, while preventing clogging in filtration. The pore size herein can be determined by reference to a nominal value of the relevant filter manufacturer.

Filtration may be carried out only one time or two or more times. When filtration is carried out two or more times, the filters used may be the same or different.

Filtration is carried out preferably at room temperature (25° C.) or lower, more preferably at 23° C. or lower, and even more preferably at 20° C. or lower, and at the same time, preferably at 0° C. or higher, more preferably at 5° C. or higher, and even more preferably at 10° C. or higher. Filtration at a temperature within the foregoing range makes it possible to reduce the amounts of particulate foreign matter and impurities dissolved in a raw material and effectively remove foreign matter and impurities.

### (Container)

The cleaning liquid (including an embodiment of a kit or a diluted solution to be described later) can be put into a given container and stored, transported and used as long as problems such as corrosion do not occur.

For the container, preferred is a container which has high cleanliness in its interior and in which leaching of impurities from the inner wall of a storage portion of the container to the liquid is suppressed, for semiconductor applications. Examples of such a container include various containers commercially available as containers for semiconductor cleaning liquids, as exemplified by, but not limited to, the “Clean Bottle” series manufactured by Aicello Corporation and “Pure Bottle” manufactured by Kodama Plastics Co., Ltd.

For the container storing the cleaning liquid, preferred is a container whose portion to contact the liquid, such as the inner wall of its storage portion, is formed from fluororesin (perfluororesin) or metal having undergone a rust proof and metal leaching prevention treatment.

The inner wall of the container is preferably formed from one or more resins selected from the group consisting of polyethylene resin, polypropylene resin, and polyethylene-polypropylene resin, or another resin different therefrom, or a metal having undergone a rust proof and metal leaching prevention treatment such as stainless steel, Hastelloy, Inconel, or Monel.

For another resin above, fluororesin (perfluororesin) is preferred. When such a container with its inner wall being formed from fluororesin is used, defects such as leaching of oligomers of ethylene or propylene can be suppressed as compared to a container with its inner wall being formed from polyethylene resin, polypropylene resin, or polyethylene-polypropylene resin.

Specific examples of such a container with its inner wall being formed from fluororesin include FluoroPure PFA composite drums manufactured by Entegris, Inc. In addition, the containers described in page 4 of JP 3-502677 A, page 3 of the description of WO 2004/016526, and pages 9 and 16 of the description of WO 99/046309 may also be used.

In addition to the foregoing fluororesin, quartz and an electrolytically polished metal material (i.e., a metal material having undergone electrolytic polishing) may also be preferably used for the inner wall of the container.

For a metal material used in manufacture of the foregoing electrolytically polished metal material, preferred is a metal material containing at least one selected from the group consisting of chromium and nickel, with the total content of chromium and nickel being more than 25 mass % based on the total mass of the metal material. Examples of such a metal material include stainless steel and a nickel-chromium alloy.

The total content of chromium and nickel in the metal material is more preferably not less than 30 mass % based on the total mass of the metal material.

The upper limit of the total content of chromium and nickel in the metal material is not particularly limited and is preferably not more than 90 mass %.

The method of electrolytic polishing of the metal material is not particularly limited, and any known methods may be used. For instance, the methods described in paragraphs [0011] to [0014] of JP 2015-227501 A and paragraphs [0036] to [0042] of JP 2008-264929 A may be used.

Preferably, the inside of the container is washed before being filled with the cleaning liquid. For a liquid used for washing, the amount of metal impurities in the liquid is preferably reduced in advance. After being manufactured, the cleaning liquid may be bottled in such containers as gallon bottles or quart bottles, transported and stored.

In order to prevent components in the cleaning liquid from changing during storage, the inside of each container may be replaced with an inert gas (nitrogen, argon or the like) having a purity of not less than 99.99995 vol % in advance. In particular, a gas with a low moisture content is preferred. While the transportation and the storage may be carried out at normal temperature, the temperature may be controlled to fall within the range of −20° C. to 20° C. to prevent the change of properties.

### (Cleanroom)

It is preferable to conduct all of manufacture of the cleaning liquid, opening and washing of the containers, handling of the cleaning liquid such as filling, process and treatment analyses, and measurements in a cleanroom. The cleanroom preferably satisfies 14644-1 cleanroom standards. The cleanroom satisfies preferably one of ISO (International Organization for Standardization) Class 1, ISO Class 2, ISO Class 3, and ISO Class 4, more preferably ISO Class 1 or ISO Class 2, and even more preferably ISO Class 1.

### <Dilution Step>

The cleaning liquid as above is preferably subjected to a dilution step in which the cleaning liquid is diluted with a diluent such as water and then used in cleaning of semiconductor substrates.

The dilution ratio of the cleaning liquid in the dilution step may be adjusted as appropriate depending on the types and contents of components and the type of semiconductor substrates to be cleaned, and the ratio of the diluted cleaning liquid to the cleaning liquid before dilution is preferably 10 to 10000 times, more preferably 20 to 3000 times, and even more preferably 50 to 1000 times in mass ratio.

The cleaning liquid is diluted preferably with water because this leads to more excellent defect suppression performance.

The change in pH from that before dilution to that after dilution (a difference between the pH of the cleaning liquid before dilution and the pH of the diluted cleaning liquid) is preferably not more than 1.0, more preferably not more than 0.8 and even more preferably not more than 0.5.

The pH of the diluted cleaning liquid is preferably more than 7.0, more preferably not less than 7.5 and even more preferably not less than 8.0 at 25° C. The upper limit of the pH of the diluted cleaning liquid is preferably not more than 13.0, more preferably not more than 12.5 and even more preferably not more than 12.0 at 25° C.

The component A content of the diluted cleaning liquid is preferably not less than 0.00003 mass %, more preferably not less than 0.00005 mass % and even more preferably not less than 0.0001 mass % based on the total mass of the diluted cleaning liquid because this leads to more excellent cleaning performance (particularly with respect to a Co-containing metal film). The upper limit thereof is not particularly limited and is preferably not more than 0.02 mass %, more preferably not more than 0.01 mass %, even more preferably not more than 0.008 mass % and particularly preferably not more than 0.005 mass % based on the total mass of the diluted cleaning liquid because this leads to more excellent corrosion prevention performance (particularly with respect to a Cu- or Co-containing metal film).

The component B content of the diluted cleaning liquid is not particularly limited and is preferably not less than 0.00005 mass %, more preferably not less than 0.00008 mass % and even more preferably not less than 0.0001 mass % based on the total mass of the diluted cleaning liquid because this leads to more excellent cleaning performance with respect to a Cu-containing metal film. The upper limit thereof is not particularly limited and is preferably not more than 0.02 mass %, more preferably not more than 0.015 mass % and even more preferably not more than 0.012 mass % based on the total mass of the diluted cleaning liquid because this leads to more excellent corrosion prevention performance (particularly with respect to a Cu-containing metal film).

The component C content of the diluted cleaning liquid is not particularly limited and is preferably 0.0003 to 0.3 mass %, more preferably 0.0005 to 0.15 mass % and even more preferably 0.005 to 0.12 mass % based on the total mass of the diluted cleaning liquid.

The water content of the diluted cleaning liquid may be the balance other than the component A, the component B, the component C, and optional components described above. The water content is, for instance, preferably not less than 90 mass %, more preferably not less than 99.3 mass %, even more preferably not less than 99.6 mass %, and particularly preferably not less than 99.85 mass % based on the total mass of the diluted cleaning liquid. The upper limit thereof is not particularly limited and is preferably not more than 99.99 mass % and more preferably not more than 99.95 mass % based on the total mass of the diluted cleaning liquid.

When the diluted cleaning liquid contains the component D, the component D content is not particularly limited and is preferably not less than 0.0001 mass %, more preferably not less than 0.0005 mass % and even more preferably not less than 0.001 mass % based on the total mass of the diluted cleaning liquid. The upper limit of the component D content is not particularly limited and is preferably not more than 0.1 mass %, more preferably not more than 0.05 mass % and even more preferably not more than 0.03 mass % based on the total mass of the diluted cleaning liquid.

When the diluted cleaning liquid contains the nitrogen-containing heteroaromatic compound, the content of the nitrogen-containing heteroaromatic compound in the cleaning liquid is not particularly limited and is preferably 0.0001 to 0.1 mass % and more preferably 0.0005 to 0.05 mass % based on the total mass of the diluted cleaning liquid.

When the diluted cleaning liquid contains the reducing agent, the reducing agent content is not particularly limited and is preferably 0.0001 to 0.2 mass % and more preferably 0.001 to 0.05 mass % based on the total mass of the diluted cleaning liquid.

When the diluted cleaning liquid contains the anionic surfactant, the content thereof is preferably 0.0001 to 0.05 mass % and more preferably 0.0005 to 0.02 mass % based on the total mass of the diluted cleaning liquid.

The chelating agent content of the diluted cleaning liquid is not particularly limited and is preferably not less than 0.0001 mass % and more preferably not less than 0.0005 mass % based on the total mass of the diluted cleaning liquid because this leads to excellent corrosion prevention performance (particularly with respect to a Cu- and/or Co-containing metal film). The upper limit thereof is not particularly limited and is preferably not more than 0.03 mass % and more preferably not more than 0.02 mass % based on the total mass of the diluted cleaning liquid.

When the diluted cleaning liquid contains the quaternary ammonium compound, the content thereof is preferably not less than 0.0005 mass %, more preferably not less than 0.001 mass % and even more preferably not less than 0.002 mass % based on the total mass of the diluted cleaning liquid because this leads to more excellent cleaning performance. The upper limit of the quaternary ammonium compound content is not particularly limited and is preferably not more than 0.1 mass %, more preferably not more than 0.05 mass % and even more preferably not more than 0.03 mass % because this can suppress a decrease in cleaning performance that may be caused by agglomeration of residue particles and/or readsorption of residues in a cleaning step.

When the diluted cleaning liquid contains the pH adjuster, the content thereof is selected depending on the types and amounts of other components and the pH of a target diluted cleaning liquid, and is preferably 0.0001 to 0.03 mass % and more preferably 0.0005 to 0.01 mass % based on the total mass of the diluted cleaning liquid.

A specific method of diluting the cleaning liquid in the dilution step is not particularly limited, and the dilution step may be carried out according to the liquid preparation step of the cleaning liquid described above. A stirrer and a stirring method used in the dilution step are also not particularly limited, and stirring may be carried out with a known stirrer whose examples are listed in the liquid preparation step of the cleaning liquid described above.

Water used in the dilution step is preferably subjected to a refining treatment in advance. Preferably, the diluted cleaning liquid obtained in the dilution step is also subjected to a refining treatment.

The refining treatment is not particularly limited, and examples thereof include an ionic component reduction treatment using ion-exchange resin or a RO membrane, and removal of foreign matter through filtration, which are described above as examples of the refining treatment for the cleaning liquid; preferably, one of these treatments is carried out.

### [Application of Cleaning Liquid]

The cleaning liquid is used in a cleaning step of cleaning a semiconductor substrate having undergone a chemical mechanical polishing (CMP) process. The cleaning liquid also can be used in cleaning of a semiconductor substrate in a semiconductor substrate manufacturing process and also used as a composition for buffing treatment, which will be described later.

As described above, the diluted cleaning liquid obtained by diluting the cleaning liquid may be used in cleaning of a semiconductor substrate.

### [Cleaning Object]

One example of a cleaning object to be cleaned with the cleaning liquid is a semiconductor substrate having metal-containing matter.

The expression “on a semiconductor substrate” in this specification includes places on the top, bottom and lateral sides of the semiconductor substrate and in a groove of the semiconductor substrate. The metal-containing matter on a semiconductor substrate includes not only metal-containing matter present directly on a surface of the semiconductor substrate but also metal-containing matter present on or above the semiconductor substrate via another layer.

A metal contained in the metal-containing matter is for instance at least one metal M selected from the group consisting of Cu (copper), Co (cobalt), W (tungsten), Ti (titanium), Ta (tantalum), Ru (ruthenium), Cr (chromium), Hf (hafnium), Os (osmium), Pt (platinum), Ni (nickel), Mn (manganese), Zr (zirconium), Mo (molybdenum), La (lanthanum), and Ir (iridium).

The metal-containing matter is not limited as long as it is a substance containing a metal (metallic atom), and examples thereof include a simple substance of the metal M, an alloy containing the metal M, an oxide of the metal M, a nitride of the metal M, and an oxynitride of the metal M.

The metal-containing matter may be a mixture containing two or more of those compounds.

The oxide, the nitride and the oxynitride above may be a composite oxide, a composite nitride and a composite oxynitride each of which contains a metal.

The metallic atom content of the metal-containing matter is preferably not less than 10 mass %, more preferably not less than 30 mass % and even more preferably not less than 50 mass % based on the total mass of the metal-containing matter. The upper limit thereof is 100 mass % because the metal-containing matter may be exactly the metal itself.

The semiconductor substrate has preferably the metal-containing matter containing the metal M, more preferably the metal-containing matter containing at least one metal selected from the group consisting of Cu, Co, W, Ti, Ta, and Ru, and even more preferably the metal-containing matter containing at least one metal selected from the group consisting of Cu, Co, Ti, Ta, Ru, and W.

The semiconductor substrate that is a cleaning object to be cleaned with the cleaning liquid is not particularly limited, and examples thereof include one having a metal wiring film, a barrier metal, and an insulating film on a surface of a wafer constituting the semiconductor substrate.

Specific examples of the wafer constituting the semiconductor substrate include wafers made of silicon-based materials such as a silicon (Si) wafer, a silicon carbide (SiC) wafer, and a silicon-containing resin wafer (glass epoxy wafer), a gallium phosphide (GaP) wafer, a gallium arsenide (GaAs) wafer, and an indium phosphide (InP) wafer.

Applicable examples of the silicon wafer include an n-type silicon wafer in which a silicon wafer is doped with a pentavalent atom (e.g., phosphorus (P), arsenic (As), and antimony (Sb)), and a p-type silicon wafer in which a silicon wafer is doped with a trivalent atom (e.g., boron (B), and gallium (Ga)). A silicon of the silicon wafer may be any of, for example, amorphous silicon, monocrystalline silicon, polycrystalline silicon, and polysilicon.

In particular, the cleaning liquid is useful for wafers made of silicon-based materials such as the silicon wafer, the silicon carbide wafer, and the silicon-containing resin wafer (glass epoxy wafer).

The semiconductor substrate may have an insulating film on the wafer described above.

Specific examples of the insulating film include silicon oxide films (e.g., a silicon dioxide (SiO₂) film and a tetraethyl orthosilicate (Si(OC₂H₅)₄) film (TEOS film)), silicon nitride films (e.g., a silicon nitride (Si₃N₄) film and a silicon nitride/carbide (SiNC) film), and low dielectric (Low-k) films (e.g., a carbon-doped silicon oxide (SiOC) film and a silicon carbide (SiC) film).

Examples of a metal film that the semiconductor substrate has include a metal film containing at least one metal selected from copper (Cu), cobalt (Co), and tungsten (W), as exemplified by a film primarily composed of copper (copper-containing film), a film primarily composed of cobalt (cobalt-containing film), a film primarily composed of tungsten (tungsten-containing film), and a metal film constituted of an alloy including one or more selected from the group consisting of Cu, Co and W.

Preferably, the semiconductor substrate has a metal film containing at least one selected from the group consisting of copper and cobalt. It is also preferable for the semiconductor substrate to have a metal film containing tungsten.

Examples of the copper-containing film include a wiring film composed only of metallic copper (copper wiring film) and a wiring film made of an alloy composed of metallic copper and other metals (copper alloy wiring film).

Specific examples of the copper alloy wiring film include a wiring film made of an alloy composed of copper and one or more metals selected from aluminum (Al), titanium (Ti), chromium (Cr), manganese (Mn), tantalum (Ta) and tungsten (W). More specifically, examples thereof include a copper-aluminum alloy wiring film (CuAl alloy wiring film), a copper-titanium alloy wiring film (CuTi alloy wiring film), a copper-chromium alloy wiring film (CuCr alloy wiring film), a copper-manganese alloy wiring film (CuMn alloy wiring film), a copper-tantalum alloy wiring film (CuTa alloy wiring film), and a copper-tungsten alloy wiring film (CuW alloy wiring film).

Examples of the cobalt-containing film (a metal film primarily composed of cobalt) include a metal film composed only of metallic cobalt (cobalt metal film) and a metal film made of an alloy composed of metallic cobalt and other metals (cobalt alloy metal film).

Specific examples of the cobalt alloy metal film include a metal film made of an alloy composed of cobalt and one or more metals selected from titanium (Ti), chromium (Cr), iron (Fe), nickel (Ni), molybdenum (Mo), palladium (Pd), tantalum (Ta) and tungsten (W). More specifically, examples thereof include a cobalt-titanium alloy metal film (CoTi alloy metal film), a cobalt-chromium alloy metal film (CoCr alloy metal film), a cobalt-iron alloy metal film (CoFe alloy metal film), a cobalt-nickel alloy metal film (CoNi alloy metal film), a cobalt-molybdenum alloy metal film (CoMo alloy metal film), a cobalt-palladium alloy metal film (CoPd alloy metal film), a cobalt-tantalum alloy metal film (CoTa alloy metal film), and a cobalt-tungsten alloy metal film (CoW alloy metal film).

The cleaning liquid is useful for a substrate having the cobalt-containing film. Of the cobalt-containing films, the cobalt metal film is often used as a wiring film, and the cobalt alloy metal film is often used as a barrier metal.

In some cases, it is preferable to use the cleaning liquid in cleaning of the semiconductor substrate having at least the copper-containing wiring film and the metal film (cobalt barrier metal), which is composed only of metallic cobalt and is a barrier metal of the copper-containing wiring film, on or above the wafer constituting the substrate, with the copper-containing wiring film and the cobalt barrier metal being in contact with each other at a surface of the substrate.

Examples of the tungsten-containing film (a metal film primarily composed of tungsten) include a metal film composed only of metallic tungsten (tungsten metal film) and a metal film made of an alloy composed of tungsten and other metals (tungsten alloy metal film).

Specific examples of the tungsten alloy metal film include a tungsten-titanium alloy metal film (WTi alloy metal film) and a tungsten-cobalt alloy metal film (WCo alloy metal film).

The tungsten-containing film is often used as a barrier metal.

The methods of forming the foregoing insulating film, copper-containing wiring film, cobalt-containing film and tungsten-containing film on the wafer constituting the semiconductor substrate are not particularly limited as long as they are known methods used in this field.

One exemplary method of forming the insulating film is a method in which the wafer constituting the semiconductor substrate is subjected to a heating treatment in the presence of oxygen gas to form a silicon oxide film, whereafter silane and ammonia gases are introduced to form a silicon nitride film by a chemical vapor deposition (CVD) method.

Exemplary methods of forming the copper-containing wiring film, the cobalt-containing film and the tungsten-containing film include a method in which a circuit is formed on the wafer having the insulating film by a known method using a resist for instance, whereafter the copper-containing wiring film, the cobalt-containing film and the tungsten-containing film are formed by plating, the CVD method, and other methods.

### <CMP Process>

The CMP process is, for instance, a process for planarizing a surface of the substrate having the metal wiring film, the barrier metal and the insulating film through a combination of a chemical action induced by use of a polishing slurry containing fine abrasive particles (abrasive grains) and mechanical polishing.

Abrasive grains (e.g., silica and alumina) used in the CMP process, metal impurities (metal residues) derived from the polished metal wiring film and barrier metal, and other impurities sometimes remain on the surface of the semiconductor substrate having undergone the CMP process. These impurities may cause, for instance, a short-circuit between wirings and adversely affect electric characteristics of the semiconductor substrate; therefore, the semiconductor substrate having undergone the CMP process is subjected to a cleaning treatment to remove these impurities from the surface of the semiconductor substrate.

Specific examples of the semiconductor substrate having undergone the CMP process include, but not limited to, a substrate having undergone the CMP process described in Journal of the Japan Society for Precision Engineering, Vol. 84, No. 3, 2018.

### <Buffing Treatment>

A surface of the semiconductor substrate that is a cleaning object to be cleaned with the cleaning liquid may be subjected to a buffing treatment after the CMP process.

The buffing treatment is a treatment for reducing impurities on a surface of the semiconductor substrate by means of a polishing pad. Specifically, a surface of the semiconductor substrate having undergone the CMP process and the polishing pad are brought into contact with each other, and the semiconductor substrate and the polishing pad are moved to slide relatively to each other while a buffing composition is supplied to the contact portion therebetween. As a consequence, impurities on the surface of the semiconductor substrate are removed due to a frictional force caused by the polishing pad and a chemical action caused by the buffing composition.

For the buffing composition, a known buffing composition may be suitably used in accordance with the type of the semiconductor substrate and the types and amounts of impurities to be removed. Components contained in the buffing composition are not particularly limited, and examples thereof include a water-soluble polymer such as a polyvinyl alcohol, water serving as a dispersion medium, and an acid such as nitric acid.

One preferable embodiment of the buffing treatment is subjecting the semiconductor substrate to the buffing treatment using the foregoing cleaning liquid as the buffing composition.

A polishing device and polishing conditions used in the buffing treatment are suitably selected from known devices and conditions in accordance with the type of the semiconductor substrate and substances to be removed. For the buffing treatment, for example, the treatment described in paragraphs [0085] to [0088] of WO 2017/169539 can be applied, and the contents thereof are incorporated in the present specification.

### [Method of Cleaning Semiconductor Substrates]

The method of cleaning semiconductor substrates is not particularly limited as long as it includes a cleaning step of cleaning the semiconductor substrate having undergone the CMP process by use of the foregoing cleaning liquid. It is preferable that the method of cleaning semiconductor substrates include a cleaning step in which the diluted cleaning liquid obtained in the foregoing dilution step is applied to the semiconductor substrate having undergone the CMP process to thereby clean the semiconductor substrate.

The cleaning step of cleaning the semiconductor substrate with the cleaning liquid is not particularly limited as long as it is a known method used for semiconductor substrates having undergone the CMP process, and any of known methods carried out in this field may be suitably applied, as exemplified by brush scrubbing cleaning that, while supplying the cleaning liquid to the semiconductor substrate, brings a cleaning member such as a brush into physical contact with a surface of the semiconductor substrate to remove residues and the like, an immersion method in which the semiconductor substrate is immersed in the cleaning liquid, a spinning (dropping) method in which the cleaning liquid is dropped while the semiconductor substrate is rotated, and a spraying method in which the cleaning liquid is sprayed. In cleaning by the immersion method, the cleaning liquid having the semiconductor substrate immersed therein is preferably subjected to an ultrasonic treatment because this can further reduce impurities remaining on the surface of the semiconductor substrate.

The cleaning step may be carried out only one time or two or more times. When the cleaning step is carried out two or more times, the same method may be repeated or different methods may be combined.

For the method of cleaning semiconductor substrates, any of a single wafer process and a batch process may be employed. The single wafer process is a method in which semiconductor substrates are treated one by one, while the batch process is a method in which a plurality of semiconductor substrates are treated at one time.

The temperature of the cleaning liquid used in cleaning of the semiconductor substrate is not particularly limited as long as it is the temperature employed in this field. While cleaning is typically carried out at room temperature (25° C.), the temperature can be arbitrarily selected in view of improvement in cleaning properties and/or suppression of damage to a member. The temperature of the cleaning liquid is preferably 10° C. to 60° C. and more preferably 15° C. to 50° C.

The cleaning time in cleaning of the semiconductor substrate depends on the types and contents of components contained in the cleaning liquid and therefore cannot be unconditionally stated; practically, the cleaning time is preferably 10 seconds to 2 minutes, more preferably 20 seconds to 1 minute and 30 seconds, and even more preferably 30 seconds to 1 minute.

The amount of supply (feed rate) of the cleaning liquid in the cleaning step of the semiconductor substrate is not particularly limited and is preferably 50 to 5000 mL/min and more preferably 500 to 2000 mL/min.

In cleaning of the semiconductor substrate, a mechanical stirring method may be used to further enhance the cleaning ability of the cleaning liquid.

Examples of the mechanical stirring method include a method involving circulating the cleaning liquid on the semiconductor substrate, a method involving flowing or spraying the cleaning liquid on the semiconductor substrate, and a method involving stirring the cleaning liquid by ultrasonics or megasonics.

The cleaning of the semiconductor substrate may be followed by a step of rinsing and washing the semiconductor substrate with a solvent (hereinafter called “rinsing step”).

The rinsing step is preferably a step that consecutively follows the cleaning step of the semiconductor substrate and that is carried out with a rinsing solvent (rinsing liquid) for 5 seconds to 5 minutes. The rinsing step may be carried out using the mechanical stirring method as above.

Examples of the rinsing solvent include water (preferably deionized (DI) water), methanol, ethanol, isopropyl alcohol, N-methylpyrrolidinone, γ-butyrolactone, dimethyl sulfoxide, ethyl lactate, and propylene glycol monomethyl ether acetate. Alternatively, an aqueous rinsing liquid with a pH of more than 8 (e.g., a diluted aqueous ammonium hydroxide) may be used.

The forgoing method of bringing the cleaning liquid into contact with the semiconductor substrate is applicable as a method of bringing the rinsing solvent into contact with the semiconductor substrate in the same manner.

The rinsing step may be followed by a drying step for drying the semiconductor substrate.

The drying method is not particularly limited, and examples thereof include spin drying, a method involving flowing dry gas on the semiconductor substrate, a method involving heating the substrate by a heating means such as a hot plate or an infrared lamp, Marangoni drying, Rotagoni drying, isopropyl alcohol (IPA) drying, and any combinations thereof.

### Examples

The present invention is described below in further detail based on examples. The materials, amounts of use, and ratios stated in examples below may be suitably modified as long as they do not depart from the scope and spirit of the present invention. Therefore, the scope of the present invention should not be construed as being limited to the examples below.

In the examples below, the pH values of cleaning liquids were measured at 25° C. with a pH meter (type: F-74, manufactured by HORIBA, Ltd.) according to JIS Z 8802-1984.

In manufacture of cleaning liquids of Examples and Comparative Examples, handling of containers and preparation, filling, storage, analysis and measurement of the cleaning liquids were all conducted in a cleanroom with the level satisfying ISO Class 2 or lower class. In measurement of the metal content of a cleaning liquid, when the content of a substance at or below the detection limit of ordinary measurement was measured, the measurement was carried out after the cleaning liquid was concentrated to 1/100 in terms of volume, and the measurement result was converted into a value of the metal content of the liquid at the concentration before the liquid was concentrated, in order to improve the measurement accuracy.

### [Raw Materials of Cleaning Liquid]

The following compounds were used to manufacture the cleaning liquids. The components used in Examples were those classified into a semiconductor grade or a high purity grade equivalent thereto.

### [Component A]

Glycine: manufactured by FUJIFILM Wako Pure Chemical Corporation

Histidine: manufactured by FUJIFILM Wako Pure Chemical Corporation

Cysteine: manufactured by FUJIFILM Wako Pure Chemical Corporation

Arginine: manufactured by FUJIFILM Wako Pure Chemical Corporation

Methionine: manufactured by FUJIFILM Wako Pure Chemical Corporation

Sarcosine: manufactured by FUJIFILM Wako Pure Chemical Corporation

β-Alanine: manufactured by FUJIFILM Wako Pure Chemical Corporation

### [Component B]

Diethylenetriaminepentaacetic acid (DTPA): manufactured by FUJIFILM Wako Pure Chemical Corporation (corresponding to the aminopolycarboxylic acid)

Ethylenediaminetetraacetic acid (EDTA): manufactured by Chelest Corporation (corresponding to the aminopolycarboxylic acid)

Trans-1,2-diaminocyclohexane tetraacetic acid (CyDTA): manufactured by FUJIFILM Wako Pure Chemical Corporation (corresponding to the aminopolycarboxylic acid)

Nitrilotris(methylenephosphonic acid) (NTPO): manufactured by FUJIFILM Wako Pure Chemical Corporation (corresponding to the polyphosphonic acid)

N,N,N′,N′-Ethylenediaminetetrakis(methylenephosphonic acid) (EDTPO): “Dequest 2066” manufactured by Thermphos (corresponding to the polyphosphonic acid)

### [Component C]

2-Amino-2-methyl-1-propanol (AMP): manufactured by FUJIFILM Wako Pure Chemical Corporation (corresponding to the amino alcohol)

### [Component D]

2-Aminopyrimidine: manufactured by FUJIFILM Wako Pure Chemical Corporation (corresponding to the anticorrosive (nitrogen-containing heteroaromatic compound))

Adenine: manufactured by FUJIFILM Wako Pure Chemical Corporation (corresponding to the anticorrosive (nitrogen-containing heteroaromatic compound))

Pyrazole: manufactured by FUJIFILM Wako Pure Chemical Corporation (corresponding to the anticorrosive (nitrogen-containing heteroaromatic compound))

3-Amino-5-methylpyrazole: manufactured by Tokyo Chemical Industry Co., Ltd. (corresponding to the anticorrosive (nitrogen-containing heteroaromatic compound))

2-Aminobenzimidazole: manufactured by FUJIFILM Wako Pure Chemical Corporation (corresponding to the anticorrosive (nitrogen-containing heteroaromatic compound))

Chlorhexidine gluconate (CHG): manufactured by FUJIFILM Wako Pure Chemical Corporation (corresponding to the chelating agent)

Gluconic acid: manufactured by FUJIFILM Wako Pure Chemical Corporation (corresponding to the chelating agent)

Citric acid: manufactured by Fuso Chemical Co., Ltd. (corresponding to the chelating agent)

Ascorbic acid: manufactured by FUJIFILM Wako Pure Chemical Corporation (corresponding to the anticorrosive (reducing agent))

Diethylhydroxylamine (DEHA): manufactured by FUJIFILM Wako Pure Chemical Corporation (corresponding to the anticorrosive (reducing agent))

Lauryl phosphoric acid ester: “Phosten HLP” manufactured by Nikko Chemicals Co., Ltd. (corresponding to the anticorrosive (anionic surfactant))

Dodecylbenzenesulfonic acid (DBSA): manufactured by FUJIFILM Wako Pure Chemical Corporation (corresponding to the anticorrosive (anionic surfactant))

### [Quaternary Ammonium Compound]

Methyltriethylammonium hydroxide (MTEAH): manufactured by FUJIFILM Wako Pure Chemical Corporation

Tetraethyl ammonium hydroxide (TEAH): manufactured by FUJIFILM Wako Pure Chemical Corporation

In addition, one of potassium hydroxide (KOH) and sulfuric acid (H₂SO₄) as the pH adjuster as well as commercial ultrapure water (manufactured by FUJIFILM Wako Pure Chemical Corporation) was used in a manufacture step of the cleaning liquids in Examples.

### [Manufacture of Cleaning Liquid]

Next, a method of manufacturing a cleaning liquid is described taking Example 1 as an example.

To ultrapure water, glycine, DTPA (diethylenetriaminepentaacetic acid), AMP (2-amino-2-methyl-1-propanol), 2-aminopyrimidine, and Phosten HLP were added in amounts corresponding to the contents shown in Tables 1 and 2 below, and subsequently the pH adjuster was added such that the pH of a prepared cleaning liquid was to be 10.5. The resulting mixture was sufficiently stirred with a stirrer, thereby obtaining a cleaning liquid of Example 1.

Cleaning liquids of Examples 2 to 45 and Comparative Examples 1 to 8 with the compositions shown in Tables 1 and 2 were manufactured according to the manufacturing method of Example 1.

In Tables, the “Amount (%)” columns provide the contents (unit: mass %) of the respective components based on the total mass of the relevant cleaning liquid. The symbol “*1” in the “Amount” column of the “pH adjuster” represents that one of H₂SO₄ and KOH was added in such an amount that the pH of the prepared cleaning liquid was to be the value shown in the “pH” column.

The values in the “Ratio 1” column each represent a mass ratio of the component B content (the total content when plural components B were used; hereinafter the same applying to other components) to the component A content (component B content/component A content).

The values in the “Ratio 2” column each represent a mass ratio of the component C content to the sum of the component A content and the component B content (component C content/(component A content+component B content)).

The values in the “Ratio 3” column each represent a mass ratio of the component D content to the sum of the component A content and the component B content (component D content/(component A content+component B content)).

The values in the “pH” column each represent the pH of the relevant cleaning liquid at 25° C. measured with the above pH meter.

### [Measurement of Metal Content]

The metal contents of the cleaning liquids manufactured in Examples and Comparative Examples were measured.

The metal contents were measured with Agilent 8800 triple quadrupole ICP-MS (for semiconductor analysis, option #200) under the following measurement conditions.

### (Measurement Conditions)

For a sample introduction system, a quartz torch, a coaxial type PFA nebulizer (for self-suction), and a platinum interface cone were used. Measurement parameters for the cool plasma condition were as follows.

Radio frequency (RF) output (W): 600

Flow rate of carrier gas (L/min): 0.7

Flow rate of make-up gas (L/min): 1

Sampling depth (mm): 18

In measurement of the metal content, metal particles and metal ions were not distinguished from each other, and the total content thereof was obtained. When two or more metals were detected, the total content of the two or more metals was obtained.

The measurement results of the metal contents are shown in the “metal content (ppb)” column of Tables 1 and 2 (unit: ppb by mass). In Tables 1 and 2, the notation “<10” represents the metal content of the relevant cleaning liquid being less than 10 ppb by mass based on the total mass of the cleaning liquid.

### [Evaluation of Cleaning Performance]

Using the cleaning liquids manufactured by the foregoing method, evaluation was made on cleaning performance (residue removal performance) when a metal film having undergone chemical mechanical polishing was cleaned.

One milliliter of the cleaning liquid of each of Examples and Comparative Examples was taken and diluted 100 times in volume ratio with ultrapure water to prepare a sample of a diluted cleaning liquid.

A wafer (diameter: 8 inches) having on its surface a metal film made of copper, tungsten or cobalt was polished with FREX 300S-II (a polishing apparatus, manufactured by Ebara Corporation). For a wafer having on its surface a metal film made of copper, the wafer was polished using CSL9044C and BSL8176C (both of which are commercial names, manufactured by FUJIFILM Planar Solutions LLC.) as polishing slurries, thereby suppressing a variation in evaluation of cleaning performance that may be caused due to a polishing slurry. Similarly, for a wafer having on its surface a metal film made of cobalt, the wafer was polished using CSL5340C and CSL5250C (both of which are commercial names, manufactured by FUJIFILM Planar Solutions LLC.) as polishing slurries. For a wafer having on its surface a metal film made of tungsten, the wafer was polished using only W-2000 (commercial name, manufactured by Cabot Corporation). The polishing pressure was 2.0 psi, and the feed rate of a polishing slurry was 0.28 mL/(min·cm²). The polishing time was 60 seconds.

Thereafter, the polished wafer was cleaned for 30 seconds using the sample of each diluted cleaning liquid whose temperature was adjusted to room temperature (23° C.), followed by drying.

The number of detected signals having the intensity corresponding to a defect with a length of 0.1 μm or more at the polished surface of the obtained wafer was counted using a defect detection apparatus (ComPlus II, manufactured by Applied Materials, Inc.), and the cleaning performance of the cleaning liquid was evaluated according to the following evaluation criteria. The evaluation results are shown in Tables 1 and 2. As the number of residue-induced defects detected at a polished surface of a wafer is smaller, the cleaning performance can be evaluated to be more excellent.

“A”: The number of defects per wafer being less than 200

“B”: The number of defects per wafer being not less than 200 and less than 300

“C”: The number of defects per wafer being not less than 300 and less than 500

“D”: The number of defects per wafer being not less than 500

### [Evaluation of Corrosion Prevention Performance]

The cleaning liquid of each of Examples and Comparative Examples was taken in an amount of 0.02 mL and diluted 100 times in volume ratio with ultrapure water to prepare a sample of a diluted cleaning liquid.

A wafer (diameter: 12 inches) having on its surface a metal film made of copper, tungsten or cobalt was cut to prepare a wafer coupon of 2 cm square. The thickness of each metal film was set to 200 nm. The wafer coupon was immersed in the sample of the diluted cleaning liquid (temperature: 23° C.) manufactured by the foregoing method and subjected to a 3-minute immersion treatment at a stirring rotational speed of 250 rpm. For each metal film, the copper, tungsten or cobalt content of the diluted cleaning liquid was measured before and after the immersion treatment. The corrosion rate (unit: Å/min) per unit time was calculated from the obtained measurement results. The corrosion prevention performance of each cleaning liquid was evaluated according to the following evaluation criteria. The results thereof are shown in Tables 1 and 2.

Note that a lower corrosion rate indicates better corrosion prevention performance of a cleaning liquid.

“A”: A corrosion rate of lower than 0.5 Å/min

“B”: A corrosion rate of not lower than 0.5 Å/min and lower than 1.0 Å/min

“C”: A corrosion rate of not lower than 1.0 Å/min and lower than 3.0 Å/min

“D”: A corrosion rate of not lower than 3.0 Å/min

TABLE 1

| | Cleaning liquid composition | | | | | | | | | | | |
|---|---|---|---|---|---|---|---|---|---|---|---|---|
| | | | | | | | | | Component D | | | |
| | | | | | | | | | Nitrogen-containing | | | |
| | | | | | | | | | heteroaromatic | | Reducing agent/ | |
| | Component A | | Component B | | | Component C | | | compound | | Chelating agent | |
| | | Amount | | Amount | Ratio | | Amount | Ratio | | Amount | | Amount |
| | Type | (%) | Type | (%) | 1 | Type | (%) | 2 | Type | (%) | Type | (%) |
| EX 1 | Glycine | 0.04 | DTPA | 0.1 | 2.5 | AMP | 6 | 42.9 | 2-Aminopyrimidine | 0.15 | — | |
| EX 2 | Glycine | 0.04 | DTPA | 0.02 | 0.5 | AMP | 6 | 100.0 | 2-Aminopyrimidine | 0.15 | — | |
| EX 3 | Glycine | 0.04 | DTPA | 0.3 | 7.5 | AMP | 6 | 17.6 | 2-Aminopyrimidine | 0.15 | — | |
| EX 4 | Glycine | 0.5 | DTPA | 0.1 | 0.2 | AMP | 6 | 10.0 | 2-Aminopyrimidine | 0.15 | — | |
| EX 5 | Glycine | 0.01 | DTPA | 0.1 | 10.0 | AMP | 6 | 54.5 | 2-Aminopyrimidine | 0.15 | — | |
| EX 6 | Glycine | 0.04 | DTPA | 0.1 | 2.5 | AMP | 1 | 7.1 | 2-Aminopyrimidine | 0.15 | — | |
| EX 7 | Glycine | 0.04 | DTPA | 0.1 | 2.5 | AMP | 3 | 21.4 | 2-Aminopyrimidine | 0.15 | — | |
| EX 8 | Glycine | 0.04 | DTPA | 0.1 | 2.5 | AMP | 8 | 57.1 | 2-Aminopyrimidine | 0.15 | — | |
| EX 9 | Glycine | 0.04 | DTPA | 0.1 | 2.5 | AMP | 10 | 71.4 | 2-Aminopyrimidine | 0.15 | — | |
| EX 10 | Histidne | 0.04 | DTPA | 0.1 | 2.5 | AMP | 3 | 21.4 | 2-Aminopyrimidine | 0.15 | — | |
| EX 11 | Cysteine | 0.04 | DTPA | 0.1 | 2.5 | AMP | 3 | 21.4 | 2-Aminopyrimidine | 0.15 | — | |
| EX 12 | Arginine | 0.04 | DTPA | 0.1 | 2.5 | AMP | 3 | 21.4 | 2-Aminopyrimidine | 0.15 | — | |
| EX 13 | Methionine | 0.04 | DTPA | D.1 | 2.5 | AMP | 3 | 21.4 | 2-Aminopyrimidine | 0.15 | — | |
| EX 14 | Sarcosine | 0.04 | DTPA | 0.1 | 2.5 | AMP | 3 | 21.4 | 2-Aminopyrimidine | 0.15 | — | |
| EX 15 | Alanine | 0.04 | DTPA | 0.1 | 2.5 | AMP | 3 | 21.4 | 2-Aminopyrimidine | 0.15 | — | |
| EX 16 | Glycine | 0.02 | DTPA | 0.1 | 2.5 | AMP | 3 | 21.4 | 2-Aminopyrimidine | 0.15 | — | |
| | Histidine | 0.02 | | | | | | | | | | |
| EX 17 | Glycine | 0.04 | DPA | 0.1 | 2.5 | AMP | 10 | 29.4 | 2-Aminopyrimidine | 0.15 | — | |
| | | | EDTPO | 0.2 | | | | | | | | |
| EX 18 | Histidine | 0.04 | EDTA | 0.1 | 2.5 | AMP | 3 | 21.4 | 2-Aminopyrimidine | 0.15 | — | |
| EX 19 | Glycine | 0.04 | CyDTA | 0.1 | 2.5 | AMP | 3 | 21.4 | 2-Aminopyrimidine | 0.15 | — | |
| EX 20 | Histidine | 0.04 | NTPO | 0.1 | 2.5 | AMP | 3 | 21.4 | 2-Aminopyrimidine | 0.15 | — | |
| EX 21 | Glycine | 0.04 | EDTPO | 0.1 | 2.5 | AMP | 3 | 21.4 | 2-Aminopyrimidine | 0.15 | — | |
| EX 22 | Histidine | 0.002 | DTPA | 0.002 | 1.0 | AMP | 0.3 | 75.0 | 2-Aminopyrimidine | 0.15 | — | |
| EX 23 | Histidine | 0.01 | DTPA | 0.05 | 5.0 | AMP | 3 | 50.0 | 2-Aminopyrimidine | 0.15 | — | |
| EX 24 | Histidine | 0.05 | DTPA | 0.3 | 6.0 | AMP | 3 | 8.6 | 2-Aminopyrimidine | 0.15 | — | |
| EX 25 | Histidine | 0.5 | DTPA | 1 | 2.0 | AMP | 10 | 6.7 | 2-Aminopyrimidine | 0.15 | — | |
| EX 26 | Histidine | 1.5 | DTPA | 2 | 1.3 | AMP | 20 | 5.7 | 2-Aminopyrimidine | 0.15 | — | |
| EX 27 | Histidine | 0.5 | | 0.1 | 0.2 | AMP | 3 | 5.0 | 2-Aminopyrimidine | 0.15 | — | |
| EX 28 | Glycine | 0.02 | DTPA | 0.1 | 2.5 | AMP | 1.5 | 10.7 | 2-Aminopyrimidine | 0.15 | — | |
| | Histidine | 0.02 | | | | | | | | | | |
| EX 29 | Glycine | 0.02 | DTPA | 0.1 | 2.5 | AMP | 2 | 14.3 | 2-Aminopyrimidine | 0.15 | — | |
| | Histidine | 0.02 | | | | | | | | | | |
| EX 30 | Glycine | 0.02 | DTPA | 0.1 | 2.5 | AMP | 3 | 21.4 | 2-Aminopyrimidine | 0.15 | — | |
| | Histidine | 0.02 | | | | | | | | | | |

EX: Example

TABLE 2

| | Cleaning liquid composition | | | | | | | | | | | | | |
|---|---|---|---|---|---|---|---|---|---|---|---|---|---|---|
| | | | | Quaternary | | | | | Evaluation | | | | | |
| | Component D | | | ammonium | | | | | Cleaning | | | Corrosion | | |
| Table 1 | Anionic surfactant | | | compound | | pH | | Metal | performance | | | prevention | | |
| (Continu- | | Amount | Ratio | | Amount | adjuster | | content | (residue) | | | performance | | |
| ation) | Type | (%) | 3 | Type | (%) | Amount | pH | (ppb) | Cu | W | Co | Cu | W | Co |
| EX 1 | Phosten HLP | 0.5 | 4.6 | — | — | *1 | 10.5 | <10 | A | A | A | B | B | B |
| EX 2 | Phosten HLP | 0.5 | 10.8 | — | — | *1 | 10.5 | <10 | A | A | A | B | B | B |
| EX 3 | Phosten HLP | 0.5 | 1.9 | — | — | *1 | 10.5 | <10 | A | A | A | B | B | B |
| EX 4 | Phosten HLP | 0.5 | 1.1 | — | — | *1 | 10.5 | <10 | A | A | A | B | B | B |
| EX 5 | Phosten HLP | 0.5 | 5.9 | — | — | *1 | 10.5 | <10 | A | A | A | B | B | B |
| EX 6 | Phosten HLP | 0.5 | 4.6 | — | — | *1 | 10.5 | <10 | A | A | A | B | B | B |
| EX 7 | Phosten HLP | 0.5 | 4.6 | — | — | *1 | 10.5 | <10 | A | A | A | B | B | B |
| EX 8 | Phosten HLP | 0.5 | 4.6 | — | — | *1 | 10.5 | <10 | A | A | A | B | B | B |
| EX 9 | Phosten HLP | 0.5 | 4.6 | — | — | *1 | 10.5 | <10 | A | A | A | B | B | B |
| EX 10 | Phosten HLP | 0.5 | 4.6 | — | — | *1 | 10.5 | <10 | A | A | A | B | B | B |
| EX 11 | Phosten HLP | 0.5 | 4.6 | — | — | *1 | 10.5 | <10 | A | A | A | B | B | B |
| EX 12 | Phosten HLP | 0.5 | 4.6 | — | — | *1 | 10.5 | <10 | B | B | B | B | B | B |
| EX 13 | Phosten HLP | 0.5 | 4.6 | — | — | *1 | 10.5 | <10 | B | B | B | B | B | B |
| EX 14 | Phosten HLP | 0.5 | 4.6 | — | — | *1 | 10.5 | <10 | B | B | B | B | B | B |
| EX 15 | Phosten HLP | 0.5 | 4.6 | — | — | *1 | 10.5 | <10 | A | A | A | B | B | B |
| EX 16 | Phosten HLP | 0.5 | 4.6 | — | — | *1 | 10.5 | <10 | A | A | A | B | B | B |
| EX 17 | Phosten HLP | 0.5 | 1.9 | — | — | *1 | 10.5 | <10 | A | A | A | B | B | B |
| EX 18 | Phosten HLP | 0.5 | 4.6 | — | — | *1 | 10.5 | <10 | A | A | A | B | B | B |
| EX 19 | Phosten HLP | 0.5 | 4.6 | — | — | *1 | 10.5 | <10 | B | B | B | B | B | B |
| EX 20 | Phosten HLP | 0.5 | 4.6 | — | — | *1 | 10.5 | <10 | B | B | B | B | B | B |
| EX 21 | Phosten HLP | 0.5 | 4.6 | — | — | *1 | 10.5 | <10 | A | A | A | B | B | B |
| EX 22 | Phosten HLP | 0.5 | 162.5 | — | — | *1 | 10.5 | <10 | B | A | B | B | B | B |
| EX 23 | Phosten HLP | 0.5 | 10.8 | — | — | *1 | 10.5 | <10 | A | A | A | B | B | B |
| EX 24 | Phosten HLP | 0.5 | 1.9 | — | — | *1 | 10.5 | <10 | A | A | A | B | B | B |
| EX 25 | Phosten HLP | 0.5 | 0.4 | — | — | *1 | 10.5 | <10 | A | A | A | B | B | B |
| EX 26 | Phosten HLP | 0.5 | 0.2 | — | — | *1 | 10.5 | <10 | A | A | A | C | B | C |
| EX 27 | Phosten HLP | 0.5 | 1.1 | — | — | *1 | 10.5 | <10 | A | A | A | B | B | B |
| EX 28 | Phosten HLP | 0.5 | 4.6 | — | — | *1 | 8.5 | <10 | B | B | B | C | A | C |
| EX 29 | Phosten HLP | 0.5 | 4.6 | — | — | *1 | 9.5 | <10 | A | A | A | B | B | B |
| EX 30 | Phosten HLP | 0.5 | 4.6 | — | — | *1 | 11.5 | <10 | A | A | A | C | C | B |

EX: Example

TABLE 3

| | Cleaning liquid composition | | | | | | | | | | | |
|---|---|---|---|---|---|---|---|---|---|---|---|---|
| | | | | | | | | | Component D | | | |
| | | | | | | | | | Nitrogen-containing | | Reducing agent/ | |
| | Component A | | Component B | | | Component C | | | heterorromatic compound | | Chelating agent | |
| Table | | Amount | | Amount | Ratio | | Amount | Ratio | | Amount | | Amount |
| 2 | Type | (%) | Type | (%) | 1 | Type | (%) | 2 | Type | (%) | Type | (%) |
| EX 31 | Histidine | 0.04 | EDTPO | 0.1 | 2.5 | AMP | 3 | 21.4 | Adenine | 0.30 | — | |
| EX 32 | Histidine | 0.04 | EDTPO | 0.1 | 2.5 | AMP | 3 | 21.4 | Pyrazole | 1.00 | — | |
| EX 33 | Histidine | 0.04 | EDTPO | 0.1 | 2.5 | AMP | 3 | 21.4 | 3-Amino-5-methylpyrazole | 0.30 | — | |
| EX 34 | Glycine | 0.02 | EDTPO | 0.1 | 2.5 | AMP | 3 | 21.4 | | | CHG | 0.8 |
| | Cysteine | 0.02 | | | | | | | | | | |
| EX 35 | Glycine | 0.02 | EDTPO | 0.1 | 2.5 | AMP | 3 | 21.4 | 2-Aminobenzimidazole | 0.30 | — | |
| | Cysteine | 0.02 | | | | | | | | | | |
| EX 36 | Sarcosine | 0.5 | DTPA | 0.1 | 0.2 | AMP | 6 | 10.0 | 2-Aminopyrimidine | 0.15 | — | |
| EX 37 | Sarcosine | 0.5 | DTPA | 0.1 | 0.2 | AMP | 6 | 10.0 | 2-Aminopyrimidine | 0.15 | — | |
| EX 38 | Sarcosine | 0.5 | DTPA | 0.1 | 0.2 | AMP | 6 | 10.0 | 3-Amino-5-methylpyrazole | 0.30 | CHG | 1.0 |
| EX 39 | Sarcosine | 0.5 | DTPA | 0.1 | 0.2 | AMP | 6 | 10.0 | 2-Aminopyrimidine | 0.15 | Gluconic acid | 0.2 |
| EX 40 | Sarcosine | 0.5 | DTPA | 0.1 | 0.2 | AMP | 6 | 10.0 | 2-Aminopyrimidine | 0.15 | Citric acid | 0.1 |
| EX 41 | Sarcosine | 0.5 | DTPA | 0.1 | 0.2 | AMP | 6 | 10.0 | 2-Aminopyrimidine | 0.15 | Adipic acid | 0.1 |
| EX 42 | Sarcosine | 0.5 | DTPA | 0.1 | 0.2 | AMP | 6 | 10.0 | 2-Aminopyrimidine | 0.15 | Ascorbic acid | 1.0 |
| EX 43 | Sarcosine | 0.5 | DTPA | 0.1 | 0.2 | AMP | 6 | 10.0 | 2-Aminopyrimidine | 0.15 | Ascorbic acid | 0.5 |
| | | | | | | | | | | | DEHA | 0.5 |
| EX 44 | Sarcosine | 0.5 | DTPA | 0.1 | 0.2 | AMP | 6 | 10.0 | 2-Aminopyrimidine | 0.15 | — | |
| EX 45 | Sarcosine | 0.5 | DTPA | 0.1 | 0.2 | AMP | 6 | 10.0 | 2-Aminopyrimidine | 0.15 | — | |
| CE 1 | Glycine | 0.01 | DTPA | 0.12 | 12.0 | AMP | 0.5 | 3.8 | 2-Aminopyrimidine | 0.15 | — | |
| CE 2 | Glycine | 0.1 | DTPA | 0.01 | 0.10 | AMP | 15 | 136.4 | 2-Aminopyrimidine | 0.15 | — | |
| CE 3 | Glycine | 0.01 | DTPA | 0.12 | 12.0 | AMP | 15 | 115.4 | 2-Aminopyrimidine | 0.15 | — | |
| CE 4 | Glycine | 0.1 | DTPA | 0.01 | 0.10 | AMP | 0.5 | 4.5 | 2-Aminopyrimidine | 0.15 | — | |
| CE 5 | Glycine | 0.02 | DTPA | 0.12 | 6.0 | AMP | 0.5 | 3.6 | 2-Aminopyrimidine | 0.15 | — | |
| CE 6 | Glycine | 0.02 | DTPA | 0.12 | 6.0 | AMP | 15 | 107.1 | 2-Aminopyrimidine | 0.15 | — | |
| CE 7 | Glycine | 0.4 | DTPA | 0.07 | 0.18 | AMP | 10 | 21.3 | 2-Aminopyrimidine | 0.15 | — | |
| CE 8 | Glycine | 0.01 | DTPA | 0.12 | 12.0 | AMP | 10 | 76.9 | 2-Aminopyrimidine | 0.15 | — | |

EX: Example
CE: Comparative Example

TABLE 4

| | Cleaning liquid composition | | | | | | | | | | | | | |
|---|---|---|---|---|---|---|---|---|---|---|---|---|---|---|
| | | | | Quaternary | | | | | Evaluation | | | | | |
| | Component D | | | ammonium | | | | | Cleaning | | | Corrosion | | |
| Table 2 | Anionic surfactant | | | compound | | pH | | Metal | performance | | | prevention | | |
| (Continu- | | Amount | Ratio | | Amount | adjuster | | content | (residue) | | | performance | | |
| ation) | Type | (%) | 3 | Type | (%) | Amount | pH | (ppb) | Cu | W | Co | Cu | W | Co |
| EX 31 | Phosten HLP | 0.5 | 5.7 | — | — | *1 | 10.5 | <10 | A | A | A | A | B | A |
| EX 32 | Phosten HLP | 0.5 | 10.7 | — | — | *1 | 10.5 | <10 | A | A | A | A | B | A |
| EX 33 | Phosten HLP | 0.5 | 5.7 | — | — | *1 | 10.5 | <10 | A | A | A | A | B | A |
| EX 34 | Phosten HLP | 0.5 | 9.3 | — | — | *1 | 10.5 | <10 | A | A | A | B | A | B |
| EX 35 | Phosten HLP | 0.5 | 5.7 | — | — | *1 | 10.5 | <10 | A | A | A | A | A | B |
| EX 36 | Phosten HLP | 0.5 | 1.1 | — | — | *1 | 10.5 | <10 | A | A | A | B | B | B |
| EX 37 | Phosten HLP | 0.5 | 1.3 | — | — | *1 | 10.5 | <10 | A | A | A | A | B | A |
| | DBSA | 0.1 | | | | | | | | | | | | |
| EX 38 | Phosten HLP | 0.5 | 3.0 | — | — | *1 | 10.5 | <10 | A | A | A | A | A | A |
| EX 39 | Phosten HLP | 0.5 | 1.4 | — | — | *1 | 10.5 | <10 | A | A | A | A | A | A |
| EX 40 | Phosten HLP | 0.5 | 1.3 | — | — | *1 | 10.5 | <10 | A | A | A | A | A | B |
| EX 41 | Phosten HLP | 0.5 | 1.3 | — | — | *1 | 10.5 | <10 | A | A | A | A | A | A |
| EX 42 | Phosten HLP | 0.5 | 2.8 | — | — | *1 | 10.5 | <10 | B | B | B | A | B | B |
| EX 43 | Phosten HLP | 0.5 | 2.8 | — | — | *1 | 10.5 | <10 | B | B | B | A | A | A |
| EX 44 | Phosten HLP | 0.5 | 1.1 | MTEAH | 1.0 | *1 | 11.5 | <10 | B | A | B | A | B | A |
| EX 45 | Phosten HLP | 0.5 | 1.1 | MTEAH | 0.5 | *1 | 11.5 | <10 | A | A | A | A | B | A |
| | | | | TEAH | 0.5 | | | | | | | | | |
| CE 1 | Phosten HLP | 0.5 | 5.0 | — | — | *1 | 10.5 | <10 | C | C | D | D | D | D |
| CE 2 | Phosten HLP | 0.5 | 5.9 | — | — | *1 | 10.5 | <10 | D | D | D | C | C | C |
| CE 3 | Phosten HLP | 0.5 | 5.0 | MTEAH | 1.0 | *1 | >12 | <10 | D | D | D | C | C | C |
| CE 4 | Phosten HLP | 0.5 | 5.9 | — | — | *1 | <8 | <10 | C | C | C | D | D | D |
| CE 5 | Phosten HLP | 0.5 | 5.0 | — | — | *1 | 10.5 | <10 | C | C | C | D | D | D |
| CE 6 | Phosten HLP | 0.5 | 5.0 | — | — | *1 | 10.5 | <10 | D | D | D | C | C | C |
| CE 7 | Phosten HLP | 0.5 | 5.0 | — | — | *1 | 10.5 | <10 | D | B | C | C | C | C |
| CE 8 | Phosten HLP | 0.5 | 5.0 | — | — | *1 | 10.5 | <10 | C | B | D | C | C | C |

EX: ExampleCE: Comparative Example}

As evident from Tables 1 and 2, it was confirmed that the cleaning liquid of the invention has excellent cleaning performance and corrosion prevention performance with respect to a copper-containing metal film and a cobalt-containing metal film.

It was confirmed that when the component A includes glycine, histidine, cysteine, or alanine, the cleaning performance is more excellent (comparison between Example 7 and Examples 10 to 15).

It was confirmed that when the component A content is not less than 0.003 mass % based on the total mass of the cleaning liquid, the cleaning performance with respect to a Co-containing metal film is more excellent (comparison between Example 22 and Example 23).

It was confirmed that when the component A content is not more than 1.0 mass % based on the total mass of the cleaning liquid, the corrosion prevention performance with respect to a Co-containing metal film is more excellent (comparison between Example 25 and Example 26).

It was confirmed that when the component B includes glycine, histidine, cysteine, or alanine, the cleaning performance is more excellent (comparison between Example 7 and Examples 10 to 15).

It was confirmed that when the component B content is not less than 0.005 mass % based on the total mass of the cleaning liquid, the cleaning performance with respect to a Cu-containing metal film is more excellent (comparison between Example 22 and Example 23).

It was confirmed that when the component B content is not more than 1.5 mass % based on the total mass of the cleaning liquid, the corrosion prevention performance with respect to a Cu-containing metal film is more excellent (comparison between Example 25 and Example 26).

It was confirmed that when the cleaning liquid contains the azole compound or the pyrazine compound as the component D (nitrogen-containing heteroaromatic compound), the corrosion prevention performance with respect to a metal film is more excellent (comparison between Example 7 and Examples 31 to 33 and 35).

It was confirmed that when the cleaning liquid contains the chelating agent as the component D, the corrosion prevention performance with respect to a metal film is more excellent (comparison between Example 36 and Examples 37 to 39).

It was confirmed that when the cleaning liquid contains the reducing agent as the component D, the corrosion prevention performance with respect to a Cu-containing metal film is more excellent (comparison between Example 36 and Example 42).

It was confirmed that when the cleaning liquid contains two or more reducing agents as the component D, the corrosion prevention performance with respect to a W-containing metal film is more excellent (comparison between Example 42 and Example 43).

It was confirmed that when the cleaning liquid contains the quaternary ammonium compound, the corrosion prevention performance with respect to a Cu- or Co-containing metal film is more excellent (comparison between Example 36 and Example 44).

It was confirmed that when the cleaning liquid contains two or more quaternary ammonium compounds, the cleaning performance with respect to a Cu- or Co-containing metal film is more excellent (comparison between Example 44 and Example 45).

In the cleaning liquid having the composition shown in Example 7 of Table 1, even when a compound selected from the compound group C shown below is used in place of AMP as the component C, the cleaning performance and the corrosion prevention performance similar to those of Example 7 can be obtained. Furthermore, in the cleaning liquid having the composition shown in Example 40 of Table 2, even when a compound selected from the compound group D shown below is used in place of citric acid as the chelating agent of the component D, or even when the phosphonic acid-based surfactant is used in place of Phosten HLP as the anionic surfactant of the component D, the cleaning performance and the corrosion prevention performance similar to those of Example 40 can be obtained.

Compound group C: monoethanolamine, 2-(methylamino)-2-methyl-1-propanol, diethanolamine, diethylene glycol amine, tris(hydroxymethyl)aminomethane, piperazine, N-(2-aminoethyl)piperazine, 1,4-bis(2-hydroxyethyl)piperazine, 1,4-bis(2-aminoethyl)piperazine, and 1,4-bis(3-aminopropyl)piperazine.

Compound group D: glycolic acid, malic acid, and tartaric acid.

In the foregoing evaluation test for cleaning performance, a wafer having on its surface a metal film made of copper, cobalt or tungsten was subjected to a CMP process, and then the polished surface of the wafer was subjected to a buffing treatment. In the buffing treatment, the samples of the cleaning liquids of Examples with the temperature adjusted to room temperature (23° C.) were each used as the buffing composition. The buffing treatment was carried out by means of the polishing apparatus used in the foregoing CMP process under the conditions of a polishing pressure of 2.0 psi, a feed rate of the buffing composition of 0.28 mL/(min·cm²) and a polishing time of 60 seconds.

Thereafter, the wafer having undergone the buffing treatment was cleaned for 30 seconds using each of the samples of the cleaning liquids of Examples with the temperature adjusted to room temperature (23° C.), followed by drying.

Using the polished surface of the wafer thus obtained, the cleaning performance and the corrosion prevention performance of each cleaning liquid were evaluated according to the foregoing evaluation test methods, and as a result the evaluation results similar to those of the cleaning liquids of Examples described above were confirmed.

What is claimed is:

1. A cleaning liquid for semiconductor substrates having undergone a chemical mechanical polishing process, the cleaning liquid comprising:
a component A that is an amino acid having one carboxyl group;
a component B that is at least one selected from the group consisting of an aminopolycarboxylic acid and a polyphosphonic acid; and
a component C that is an aliphatic amine (provided that the component A, the aminopolycarboxilic acid and a quaternary ammonium compound are excluded),
wherein a mass ratio of a content of the component B to a content of the component A is 0.2 to 10, and
a mass ratio of a content of the component C to a sum of the content of the component A and the content of the component B is 5 to 100.

2. The cleaning liquid according to claim 1,
wherein the component A includes at least one selected from the group consisting of glycine, histidine, cysteine, arginine, methionine, sarcosine, and alanine.

3. The cleaning liquid according to claim 1,
wherein the component B includes at least one selected from the group consisting of diethylenetriamine pentaacetic acid, ethylenediamine tetraacetic acid, trans-1,2-diaminocyclohexane tetraacetic acid, nitrilotris(methylenephosphonic acid), and ethylenediamine tetra(methylenephosphonic acid).

4. The cleaning liquid according to claim 1,
wherein the component C includes an amino alcohol.

5. The cleaning liquid according to claim 1, further comprising a component D that is at least one selected from the group consisting of a nitrogen-containing heteroaromatic compound, a reducing agent, an anionic surfactant, and a chelating agent (provided that compounds included in the component A, the component B and the component C are excluded).

6. The cleaning liquid according to claim 5,
wherein a mass ratio of a content of the component D to the sum of the content of the component A and the content of the component B is 0.1 to 20.

7. The cleaning liquid according to claim 1, further comprising a quaternary ammonium compound that is a compound having a quaternary ammonium cation, or a salt thereof.

8. The cleaning liquid according to claim 7,
wherein the quaternary ammonium cation in the quaternary ammonium compound has an asymmetric structure.

9. The cleaning liquid according to claim 7,
wherein the quaternary ammonium compound comprises two or more quaternary ammonium compounds.

10. The cleaning liquid according to claim 1, further comprising two or more reducing agents.

11. The cleaning liquid according to claim 1,
wherein the cleaning liquid has a pH of 8.0 to 12.0 at 25° C.

12. The cleaning liquid according to claim 1,
wherein the semiconductor substrate has a metal film containing at least one selected from the group consisting of copper and cobalt.

13. The cleaning liquid according to claim 1,
wherein the semiconductor substrate has a metal film containing tungsten.

14. A method of cleaning semiconductor substrates, the method comprising a step of cleaning a semiconductor substrate having undergone a chemical mechanical polishing process by applying the cleaning liquid according to claim 1 to the semiconductor substrate.
